(19) United States
(12) Patent Application Publication
(10) Pub. No.: US 2006/0124166 A1
(43) Pub. Date: Jun. 15, 2006

(54) Method and apparatus for achieving worldwide reduction of carbon dioxide emissions and deforestation

(76) Inventor: Maarten Martinus Romijn, Aachen (DE)

Correspondence Address: BROOKS KUSHMAN P.C., 1000 TOWN CENTER, TWENTY-SECOND FLOOR, SOUTHFIELD, MI, 48075, US

(21) Appl. No.: 10/559,348

(22) PCT Filed: May 19, 2004
(86) PCT No.: PCT/US04/15817

§ 371 Date: Dec. 5, 2005

Related U.S. Application Data
(63) Continuation-in-part of application No. 10/801,864, filed on Mar. 17, 2004.
(60) Provisional application No. 60/475,468, filed on Jun. 4, 2003.
(60) Provisional application No. 60/475,468, filed on Jun. 4, 2003.

(51) Int. Cl. H01L 25/00

(52) U.S. Cl. 136/246

(57) ABSTRACT

Method and apparatus enabling worldwide reduction of carbon dioxide emissions and/or deforestation, personal clean energy system providing for cooking and/or electricity needs, earning emission credits, monetizing values of tradable emission rights/credits accruing from emissions avoided by using the apparatus to pay for the cost of the apparatus and/or to provide ongoing revenue thereby inducing many people to substitute carbon containing fuels for cooking and/or electricity needs by a synergic combination of cooking 0 and/or electricity generation 21 on sunlight H through a low cost two-axis easy sun tracking mechanism including a bendable mirror 14 having variable curvatures rₘ and tilt angles sₘ optimized for the solar altitudes αₛ at the latitudes, seasons and day times from equator to arctic, resulting in greatly augmented cooking power enabling high quality meals 0 through much shorter cooking times and/or longer/higher PV cell 21 outputs charging batteries 24 powering lights, refrigerator, television, computer, enabling worldwide education and sustainable development.

### CROSS-REFERENCE TO RELATED APPLICATIONS

Specific reference is made to the provisional application for patent for the present invention filed by this applicant/inventor in the United States Patent and Trademark Office on the fourth of June of the year two thousand and three (Jun. 4, 2003), for which provisional application for patent the United States Patent and Trademark Office has issued application number 60/475,468, confirmation number 9680 and filing receipt barcode number *OC000000010443224*, which was mailed by the United States Patent and Trademark Office to this applicant/inventor on the eighth of July of the year two thousand and three (Jul. 8, 2003). Applicant/inventor has filed a non-provisional utility patent application for a U.S patent for the present invention in the United States Patent and Trademark Office on the seventeenth of March of the year two thousand and four (Mar. 17, 2004), return postcard identification: 15535 U.S. PTO 10/801,864-031704.

Inventor: Romijn, Maarten Martinus

Citizenship: Citizen of the Netherlands

Residence: Nr. 10 Grindelweg, Aachen 52076, Germany

### METHOD AND APPARATUS FOR ACHIEVING WORLDWIDE REDUCTION OF CARBON DIOXIDE EMISSIONS AND DEFORESTATION

### TECHNICAL FIELD

The present invention relates generally to the urgent need to reduce worldwide emissions of harmful gases including greenhouse gases such as carbon dioxide.

More particularly the ambition of the present invention is to provide practical and cost effective means enabling worldwide reduction of emissions of greenhouse gases including carbon dioxide and other harmful gases emanating from the widespread burning of carbon containing fuels including fuel wood for cooking purposes. In this context the present invention aims to provide strong incentives for the replacement of unaccounted polluting fuels burned for cooking purposes, by sunlight, as a convenient clean and safe heat and/or light source for cooking and/or electricity generation.

With the above considerations in mind the present invention provides a method and apparatus capable of augmenting convenience of cooking and/or electricity generation on sunlight to such a high level that cooking and/or electricity generation on sunlight becomes more convenient worldwide than cooking on carbon containing fuels like fuel wood.

### BACKGROUND OF THE INVENTION

Gross National Product (GNP) in many countries of the world is directly related to the use of carbon containing fuels, resulting in emissions of carbon dioxide and other harmful gases and soot. From nation to nation GNP in U.S. dollars per metric ton of nationally accounted carbon dioxide emitted has varied considerably. For example, in the year 2000 from U.S.$4,110.—per metric ton in Japan to U.S.$1,785.—per metric ton in the U.S.A. to U.S.$ 365,—per metric ton in China. For the world, on average, Gross World Product (GWP) in the year 2000 amounted to about U.S.$1,314.—per accounted metric ton of carbon dioxide emitted. Reducing carbon dioxide emissions, nationwide and/or worldwide by curtailing economic activity casu quo economic growth, is a very costly option.

Until recently industrialized nations in North America, Europe and Asia were considered to dominate the use of fossil fuels resulting in vast carbon dioxide emissions causing global warming. The cost of carbon dioxide sequestration from fossil fuel fired power stations in Europe and the U.S.A. is reported in “Modern Power Stations”, 7 Oct. 2001 to be about U.S.$50.—per metric ton of carbon dioxide removed. In Europe, industries exceeding their carbon dioxide emission targets may presently be taxed the equivalent of U.S.$40.—for every excess metric ton of carbon dioxide emitted, as of 2008 European industries may be taxed as much as the equivalent of U.S.$100.—per excess metric ton of carbon dioxide emitted above their allowable targets. In the United Kingdom the government's consultation document 2001 (HMSO—London) on the “Renewable Obligation” indicated that a cost of U.S.$120.—per metric ton of carbon dioxide avoided represented “good value”.

A more compelling need for reduction of carbon dioxide and other harmful gas emissions has become evident recently from the “Asian Plume” caused by highly polluting, inefficient burning of carbon containing fuels like fuel wood for cooking purposes and causing widespread air pollution from Asia as far as the Mediterranean, as reported from the “Indian Ocean Experiment” in “Science”, 9 Feb. 2001 and 25 Oct. 2002.

A recent (2000) large survey in rural areas at 15° North latitude in India, as presented in “Energy Conversion and Management” 41, 2000, pages 775-831, reports average firewood consumption per person per day of 2.10 kilos for cooking plus 1.39 kilos per day for water heating. This adds up to fuel wood needs of 1.275 metric tons per person per year and consequently to unaccounted annual emissions of carbon dioxide in the order of 3.0 metric tons per person per year. If this recent figure is used as representative for a rural world average, presently unaccounted emissions of carbon dioxide from worldwide fuel wood burning add up to some six thousand million metric tons per annum.

Quality of the cooked foods is poor, local overheating causes carcinogens such as acrylamides from locally overheated carbohydrates in the grains or potatoes being cooked.

The efficiency of cooking stoves in use is extremely poor. Only some 10 (ten) percent of the energy content of the firewood fuel is transferred to the food or beverage to be cooked casu quo to be heated. Some 90 (ninety) percent of the energy is lost, combustion quality is very poor, the associated smoke and soot are extremely unhealthy for the cooks, the bystanders and the environment.

The relevance of cooking on light is described in a commentary called “Cooking in the Sunshine”, in “Nature”, dated Nov. 29, 1990, volume 348, pages 385-386. “Nature” reports that in 1990 worldwide two thousand million people depended on wood for cooking and that half the annual world wood harvest of three thousand million metric tons was used as a fuel. A similar number of people have no access to electricity, not even for such basic needs as a light bulb or a small refrigerator. In developing countries over fifty percent of all energy was used to prepare food. Firewood is in short, declining supply, villagers in many rural areas in India now have to forage for firewood some eight hours per day. The cutting of firewood causes deforestation and destruction of wildlife. For every metric ton of firewood burned, some 2.35 metric tons of carbon dioxide accompanied by a host of other harmful anthropogenic gases and soot are emitted.

Apart from the scarcity of firewood and resulting deforestation the fuel wood problem is aggravated by increased public awareness of global greenhouse effects caused by carbon dioxide emissions. Said burning of firewood for cooking purposes causes presently unaccounted carbon dioxide emissions in the order of six thousand million metric tons per annum, which—in perspective—is about equal to the total carbon dioxide emissions of Asia or the U.S.A. or to two times the total carbon dioxide emissions of the European Union. Compensating six thousand million metric tons of presently unaccounted carbon dioxide emissions emanating from carbon containing fuels by carbon dioxide sequestration at fossil fuel fired power stations in industrialized nations would result in a recurring cost in the order of 300 billion U.S. dollars per year.

In the year 2000, for the world, average GWP amounted to about U.S.$1,314.—per accounted metric ton of carbon dioxide emitted. For the rural population, as per above survey in India, with an average family of 5.5 members having an income of less than U.S.$150.—per family per year, the contribution to GWP is not much more than U.S.$10.—per metric ton of unaccounted carbon dioxide emitted. In other words, based on present levels of technology, the industrial world emits less than one metric ton of carbon dioxide for every thousand U.S. dollars worth of GWP achieved, whereas the fuel wood burning rural world emits in the order of one hundred metric tons, or over two orders of magnitude more carbon dioxide for every thousand U.S. dollars worth of GWP achieved. An analysis of bright sunshine hours available during the year in a typical North Indian environment at Jodhpur (26° N) has shown that for 5 333 days out of 365 bright sunshine is available for more than four hours per day, of which for 321 days bright sunshine is available for more than six hours per day. Rigorously used an advanced hot box type light cooker could save 321 times 3.49 kilos, is 1.12 metric tons of firewood per person per year casu quo over six metric tons per family per year, simultaneously reducing carbon dioxide emissions by 2.65 metric tons per person per year, casu quo by some 14.5 metric tons per average family per year. Similarly casu quo additionally said advanced hot box type light cookers replacing widely used kerosene burning cookers could save on average more than a barrel of oil per person per year. More than 80 (eighty) percent of the world's population lives in the sunbelt area, between the 40° North parallel (the Beijing-Korea-Japan-New York-Madrid-Ankara-Tasjkent latitude) and the 40° South parallel (the Cape Town-Melbourne-Buenos Aires latitude). In said sunbelt area and beyond an advanced hot box type light cooker of the present invention can be made to provide year-round net to food peak cooking power of 2,000 watts per square meter and/or photovoltaic cell peak sunlight irradiation of 1,500 watts per square meter of hot box light aperture area. For a six member family a 0.35 meter×0.70 meter light aperture cooker enables convenient cooking, for a four person family a 0.35 meter×0.50 meter or a 0.25 meter×0.70 meter light aperture is convenient, for a two adults family a 0.25 meter×0.50 meter light aperture is convenient. For one person a 0.25 meter×0.25 meter light aperture cooker is convenient. The estimated cost of said light cookers can be paid for in less than a year by the commercial trade value of the emission rights of the carbon dioxide avoided through the use of said light cookers. The method of reducing carbon dioxide emissions emanating from the widespread use of fuels like fuel wood for cooking purposes is therefore a most cost effective and practical method for achieving worldwide reduction of carbon dioxide emissions, thereby simultaneously mitigating present and future constraints on worldwide economic growth as may become imposed by present casu quo future carbon dioxide emission limits. At the same time said method provides the following additional benefits:
a) Method enables cooking of better tasting and healthier dishes.
b) Method enables cleaner, safer and healthier ways of cooking.
c) Method enables freeing many millions of people from the chores of hunting for ever scarcer fuel wood and of attending to smoking, badly smelling cooking fires causing widespread lung and eye diseases. Any time required for sun-tracking of the apparatus of the present invention is far less than the time required to keep present cooking fires under control and/or time required to find wood.
d) Method reduces the need for fuel wood, reduces deforestation and destruction of wildlife.

In another context, many of serious and extended forest fires, such as experienced each year in e.g. Asia, Australia, Europe and the U.S.A., may be reduced in frequency if cookers on light with augmented power can be made available and convenient for use instead of the wood burning camp fires and barbecues now being popular for outdoor cooking.

In yet another context electricity may be produced efficiently and conveniently by photovoltaic cells positioned under an optimized mirror component of the apparatus of the present invention, thereby enabling worldwide affordable access to electricity, light and education, casu quo further worldwide reduction of emissions.

### BACKGROUND ART

Despite many efforts in industrialized countries to reduce carbon dioxide emissions for example through more fuel efficient cars, through more efficient power stations firing natural gas instead of coal and through the recently started practice in Japan of costing emissions into the price of industrial casu quo consumer products, carbon dioxide emissions are still rising in virtually every country on earth with the fastest most worrying rise in developing countries.

Most of said prior art casu quo state of the art efforts to reduce emissions of carbon dioxide were casu quo are being made in industrial areas as observed through prior art searches carried out in US classification 702/23, 364/493 and related classifications as well as in international classification G06F and related applications wherein numerous prior art patent references were found of which for example U.S. Pat. No. 6,691,044 assigned to Toshiba Corporation for a “product environmental load evaluation method” is a typical example. The prior art casu quo the state of the art fails to disclose or suggest a method casu quo a mechanism capable of mobilizing casu quo inducing many people in developing countries casu quo in rural areas to reduce casu quo to avoid their carbon dioxide emissions mainly emanating from their burning of carbon containing fuels for cooking and/or water heating needs. In emissions perspective, the carbon dioxide emissions that can be avoided by one family using the efficient solar cooker/PV electricity generator of the present invention, qualified for the accrual of tradable carbon dioxide emission rights casu quo tradable carbon dioxide emission credits through a mechanism of quality assurance and/or registration numbers casu quo country and/or state license plate numbers can compensate the carbon dioxide emissions of about half a dozen compact cars, or can equal the carbon sink capacity of one acre of mature tropical forest.

Numerous prior art references describing photovoltaic solar cells, hereinafter called PV cells, for electricity generation were screened through prior art searches in US classification 257/457 and related classifications as well as in international classification H01L/27 and related classifications, of which U.S. Pat. No. 6,696,731 assigned to Samsung corporation is a typical example. The prior art pertaining to PV cells casu quo PV cell modules for electricity generation fails to disclose or suggest a combination of PV cells and a solar cooker for simultaneous casu quo alternating cooking and/or electricity generating operations.

Heretofore, numerous efforts have been made to develop a practical and workable solar cooker. The following noted patents found as a result of patent searches carried out in U.S. classification 126 and related classifications as well as in international classification F24J2 and related classifications are exemplary of the known efforts made by others to attain a practical and workable solar cooker; viz. U.S. Pat. Nos. 820,127; 1,074,219; 1,158,175; 2,859,745; 2,909,171; 2,994,318; 3,038,463; 3,053,248; 3,896,786;3,938,497; 4,077,391; 4,082,079; 4,083,357; 4,130,106; 4,220,141; 4,236,508; 4,262, 660; 4,281,644; 4,284,071; 4,292,957; 4,442,828; 4,446,854; 4,561,425; 4,583,521; 4,696,285; 4,848,320; 4,850,339; 4,913,130; 5,090,399; 5,113,845; 5,139,010; 5,524,610; 5,617,843; 5,893,360; 6,606,988; and viz. WO8703073; WO9739669; WO02075226; WO03006894; EP0099423; CN1035349; CN1040673; CN2098654U; CN2169093U; CN2181658U; CN2252966U; CN2374861U; CN2443681U; CN2451967U; CN2569029U; IN155889; IN158556; IN158891; IN159461; IN159541; IN162938; IN175856; IN178752; IN181453; IN184675; DE3120520; DE3545890; DE3607484; DE3611375; DE3616007; DE3706348; DE4009754; DE4142119; DE4218403; DE4308458; DE4338736; DE19545108; DE19603742; DE19807465; JP56097755; JP63306357; JP2101350; JP4366363; JP8233374; JP10094480; JP11325612; JP2000146309; JP2001183012; JP2001238712; FR2565678; FR2588644; FR2596503; FR2692659; FR2692660; FR2787867; FR2801097; GB2341675.

The prior art concentrating type of solar cookers such as for example the parabolic mirror type having the mirror positioned under the cooking vessel has too many drawbacks such as for example cumbersome sun tracking requirements, local hot spots burning the food, glare blinding the cook, sensitivity to wind and food spills fouling said mirror, to be considered for mass cooking. Generally the prior art fails to quantify solar energy collectable by the prior art solar cooker embodiments and also fails to disclose or suggest prior art solar cooker performance in terms of net to food cooking power achievable in operation of said prior art solar cooker embodiments, the foregoing applies to all prior art solar cooker concepts including prior art solar cooker embodiments of the hot box type and of the concentrating flat mirror casu quo the concentrating curved mirror type.

An “Evaluation of the International Standard Test Procedure for testing Solar Cookers and Reporting Performance” is presented by P. A. Funk et al. in “Solar Energy” 2000, volume 68, pages 01-07, and references therein.

All patents, articles, references, standards and the like cited herein are incorporated herein by reference in their entirety.

State-of-the-art hot box type cooker designs have in common that solar radiation enters the cooker cavity and is absorbed by and converted to heat on a blackened sheet of metal (“the absorber”) functioning as heat conducting walls and floor of the cooker cavity. A representative design of a state-of-the-art hot box type solar cooker is shown in FIG. 1, in a sectional view showing the cooker cavity 0, the cooking vessel 2 standing on the non-spectrally selective absorber plate 1, the insulation 3, the double glazed hinged lid 4 openable for access to the cooker cavity casu quo the cooking vessel, the reflecting “booster” lid 5 serving in the closed non-used position as protection of the glazed lid and the hinges 6. The cooking performance of hot box solar cookers according to the state-of-the-art is poor, especially so when solar radiation and ambient temperature are low, such as is the case in winter and also in the other seasons during morning hours and late afternoon hours, when the sun is low and the angle of incidence of beam radiation is large. For the best state-of-the-art hot box type solar cookers the cooking time around mid-day in the summer for a dish is about three hours. During said three hours the position of the cooker box must be adjusted every half-hour, tracking the sun to obtain radiation in the cooker aperture. State-of-the-art cookers are characterized by a very slow build-up of net to food cooking power, high heat loss through the light admitting aperture and are suitable only for the boiling type of cooking where cooking temperature does not exceed about one hundred centigrade. The quantities of heat required for physical and chemical changes involved in the cooking process proper are small relative to the sensible heat required to bring food to boiling temperature and to compensate heat losses that occur during warming up and cooking. Even during optimum conditions of solar radiation the temperatures required for frying or baking cannot be sustained. Because the dominant mode of heat transfer to the food is by conduction from the absorber 1 to the vessel bottom 2 cooking time exponentially increases when the area ratio of absorber area to vessel bottom area decreases, in other words when more vessels are placed in the cooker cavity. Poor heat transfer between the absorber and any vessel bottom leads to high temperatures of the non-spectrally selective absorber surface especially so in absorber areas at a distance from the vessel edge, and consequently high heat losses. The net sum is that typical state-of-the-art hot box type solar cookers having approximately 56 cm×56 cm×20 cm box dimensions, and about 46 cm×46 cm light aperture, having an estimated local cost in the order of U.S.$50.—, can only provide a net to food cooking power of about 25 watts on clear sunny days in the winter at 24° latitude casu quo about 125 watts/m², as shown in FIG. 2C. State-of-the art solar cooker designs fail to disclose or suggest inexpensive means to obtain higher net to food cooking power casu quo desirable cooking frequencies casu quo warm-keeping of meals on the table or under off-sunshine conditions. State-of-the art photovoltaic (hereinafter called PV) electricity generation systems of the non-tracking type are characterized by a slow build-up of net electric power delivery, especially so at low and/or unfavorable angles of incidence of sunlight on the PV cells. State-of-the art cooker designs fail to disclose or suggest any combination of convenient cooking and convenient electricity generating operations in one apparatus wherein PV modules are compelled by the movement of said apparatus to track the sun in a two-axis manner resulting simultaneously in optimum angles of sunlight incidence on said PV cells and said cooker. State-of-the art solar cooking designs fail to disclose or suggest any method and/or apparatus capable of inducing many people to substitute carbon containing fuels for cooking, by sunlight. The state-of-the art fails to disclose or suggest any method casu quo any mechanism whereby trade values of emission rights casu quo carbon credits accruing from emissions avoided through the use of the present method and/or apparatus can be monetized casu quo used to pay for the cost of said method and/or said apparatus and/or to create a source of ongoing revenue for the users and/or governments promoting the use of said method and apparatus. The present invention teaches such a method and apparatus offering many millions of people a substantially expanded latitude, light, temperature and time operating window for convenient cooking and convenient electricity generation on sunlight, thereby not only offering attractive new cooking operations, but also affordable access to electric light, refrigerator, television, computer, casu quo entertainment and education and offering many governments and/or organizations a practical means for sustainable development that can be implemented immediately.

### DISCLOSURE OF THE INVENTION

The present invention relates generally to the urgent need to reduce worldwide emissions of harmful gases including greenhouse gases such as carbon dioxide, as an estimated six thousand million metric tons of carbon dioxide emitted annually are emanating from carbon containing fuels such as firewood burned for cooking and/or water heating purposes by some two to three thousand million people living in developing countries casu quo in rural areas of the earth the method and apparatus of the present invention is conceived casu quo expected to qualify for the accrual of tradable carbon dioxide emission rights casu quo of tradable carbon dioxide emission credits that can be monetized to pay for the cost of the method and apparatus of the present invention and/or to create a source of ongoing revenue, thereby inducing many people to substitute said carbon containing fuels by sunlight for cooking and/or water heating and/or electricity generation and inducing many governments and/or non government organizations to support casu quo to enable the introduction to casu quo the continued use by their people of the method and apparatus of the present invention. Accordingly the present invention provides method and apparatus enabling gainful replacement of highly polluting fuels, such as for example fuel wood for cooking purposes by light, through greatly augmented convenience of cooking on light. Convenience of cooking on light is augmented according to the present invention by increasing the useful net to food cooking power of a hot box type solar cooker especially at low solar altitudes, such as prevail in early morning and late afternoon worldwide and at higher latitudes by an order of magnitude compared to state-of-the-art hot box type solar cookers presently available.

Optimized light energy transfer from available solar radiation to foods, beverages and other substances to be cooked casu quo heated is provided through the use of a hot box type light cooker comprising a cavity having well insulated side walls and lower and upper horizontal walls of a heat resistant heat conducting material coated on the illuminated side with a long-life heat resistant spectrally selective coating capable of converting light to heat. Said spectrally selective coating having a high absorptivity coefficient (α) for incoming light in combination with a low emissivity coefficient (ε) for reversed radiation of heat. Sheets of a suitable heat resistant transparent material, such as for example glass or Teflon®, are provided under said lower horizontal wall and above said upper horizontal wall at a distance from said selective coatings in order to protect said selective coatings and to provide an insulating layer of air to minimize heat losses to the ambient.

Net to food cooking power augmentation according to the present invention is achieved in major part by heating the food from below with heat provided by an approximately horizontally positioned lower heat conducting wall heated by reflected light reaching the underside, the spectrally selective coated side, of said lower heat conducting wall. Non-conventional reflected solar radiation is provided to said lower heat conducting wall from below through the use of concave bent and/or bendable mirrors/reflectors having variable tilt angles and/or curvatures optimized for desired cooking casu quo heating operations and for the solar altitudes at the time of the days, seasons and latitudes from equator to arctic where the light cooker may be used. Said mirrors/reflectors are positioned under the hot box type light cooker, extending sideways and upwards therefrom in such a manner that they direct, in an optimum manner, a major part of the solar radiation, incident on the light cooker assembly, to the underside of the light cooker where light is spontaneously converted by the spectrally selective coating to heat, which heat is conducted instantly, with minimum resistance, to foods/beverages to be cooked/heated. Conventional direct solar radiation is provided from above to the upper heat conducting wall on the spectrally selective coated side, where light is spontaneously converted to heat, which heat is conducted instantly with minimum resistance and radiated to the food located below said upper heat conducting wall.

Convenience of cooking is further augmented according to the present invention by cooking directly on and in said heat conducting walls, said walls having been shaped by pressing said walls into tray-shaped thin-walled cooking trays. The use of conventional cooking pots is thereby avoided and heat transfer resistance to food reduced by an order of magnitude.

A further augmentation of convenience of cooking according to the present invention is provided by serving the cooked hot food directly onto the table in the well insulated hot box tray, in order to keep the food warm during the meal.

The method and apparatus of the present invention are characterized by enabling a fast build-up of a convenient level of cooking power and/or a convenient level of electricity generating power within about half an hour from sunrise and maintaining said convenient levels of cooking power and/or electricity generating power late in the day, until sunset.

The method and apparatus of the present invention can have a variety of embodiments, in one aspect ranging in size and net to food cooking power from a basic method and apparatus having light-acquiring apertures casu quo windows of identical sizes and an upper mirror of the same or larger sizes as said windows, to a method and apparatus having a wider first window and having an upper mirror of the same or larger sizes than said wider first window. In another aspect, said cooking cavity may be positioned approximately horizontally into or above a half-barrel shaped concave reflective cavity, for cooking foods. Alternatively for cooking soups or heating water said cooker cavity may be positioned vertically, either sideways from a quarter-barrel shaped concave reflective cavity providing light to one side of said cooker cavity or into a half-barrel shaped concave reflective cavity providing light to two sides of said cooker cavity. In another embodiment, for alternating and/or simultaneous electricity generation, PV cells may be positioned temporarily and/or permanently under said upward mirror. PV electricity power generation according to the method and apparatus of the present invention is characterized by enabling a fast build-up of high levels of PV electricity generating power that can be an order of magnitude higher than present PV power levels provided by state-of-the art non-tracking PV systems, especially so at low solar altitude angles as prevailing in winters, higher latitudes, early mornings and late afternoons.

In yet another embodiment a halogen light source may be provided for positioning above or under said cooker cavity for cooking operations when sunlight is not available casu quo marginal and electricity can be made available.

Cooking power, attainable worldwide at different latitudes (64° North-0° Equator-64° South) and different seasons (winter, spring/autumn, summer) is shown simulated in FIG. 11. PV power cell light irradiation attainable worldwide at said different latitudes and in said different seasons is shown simulated in FIG. 12.

### OBJECTS OF THE INVENTION

The present invention relates generally to the urgent need to reduce worldwide emissions of harmful gases including greenhouse gases such as carbon dioxide.

Accordingly it is an object of the present invention to provide a cost effective, financially attractive and convenient method and apparatus inducing many people worldwide to rapidly substitute polluting carbon containing fuels for cooking and/or electricity generation by an abundant clean non-commercial safe heat source—sunlight. Therefore method and apparatus are provided capable of augmenting attractiveness and convenience of cooking and/or electricity generation on sunlight to such a high level that cooking and/or electricity generation on sunlight can rapidly become more attractive and more convenient worldwide than cooking and/or electricity generation on burning carbon containing fuels, such as for example fuel wood. Cost effectiveness and financial attractiveness of cooking and/or electricity generation on sunlight is augmented according to the present invention by providing method and apparatus qualifying for the accrual of tradable carbon dioxide emission rights casu quo tradable carbon dioxide emission credits that can be monetized to pay for at least the cost of said method and apparatus and alternately and/or additionally also create a source of ongoing revenue for the users and/or for governments and/or organizations that promote the introduction and continued use of the method and apparatus of the present invention. For said qualifying, said apparatus is preferably manufactured casu quo produced under a mechanism of quality assurance and equipped with punched-in registration numbers casu quo with punched-in country casu quo state license plate numbers qualifying said apparatus for accrual of tradable carbon dioxide emission rights casu quo tradable carbon dioxide emission credits. Convenience of cooking on sunlight is augmented according to the present invention by increasing the useful net to food cooking power of a hot box type light cooker by an order of magnitude compared to state-of-the-art hot box type solar cookers having the same hot box dimensions and simultaneously decreasing the cost per watt net to food cooking power casu quo the cost per watt net electric power to a better than competitive level.

Convenience of cooking and/or electricity generation on sunlight is further augmented by the present invention by extending the operating window in the following aspects:
Enabling cooking and/or electricity generation on sunlight more hours per day worldwide even when the sun is at low altitude:
   a) All year from sunrise to sunset.
   b) In the solar winter when the sun is low.
   c) At high latitudes, where the sun is low.
Enabling cooking at higher temperatures for cooking operations, such as for example steaming, frying, baking, simmering, roasting.
Enabling reduction of cooking time from presently about three hours per meal to about one hour per meal, thereby also making said apparatus available for electricity generation most of a day.
Enabling reduction of sun tracking requirements to one per meal.
Enabling professional mass cooking on sunlight in restaurants, cafeterias, schools, hospitals, holiday camps, refugee camps, emergencies upon breakdown of conventional energy infrastructure.
Enabling mobile cooking operations and/or electricity generation on sunlight, like barbecues, by vacationers, mountaineers, scouts and the like.
Enabling heat processing in the broadest sense of foods, beverages and other suitable substances, resulting in:
   a) Perfectly homogeneous cooking of foods on light, no local overheating or burning of food, excellent quality, taste, texture and vitamin content of the cooked meals, soups, beverages.
   b) Zero emission of smoke, soot, carcinogens, carbon dioxide and other pollutants detrimental to the environment, the cooks and bystanders.
   c) No carcinogens in the cooked food, no carcinogens breathed in.
   d) Cooking independence, avoiding short circuits, power failures, gas explosions, fuel spills, burns, fires, forest fires, deforestation, wildlife destruction.
Enabling a method casu quo a mechanism whereby trade values of emission rights casu quo emission credits accruing from emissions avoided through the use of the method and apparatus of the present invention can be monetized to pay for the cost of said method and apparatus and/or to create a source of ongoing revenue casu quo used to offset the cost of present and/or future environmental obligations and duties or taxes such as for example carbon taxes casu quo carbon dioxide emission taxes.
Enabling better quality of life for many millions of people through improved health standards by reducing emissions of harmful gases and cooking-originated carcinogens in meals and by providing affordable access to fuel-free cooking and electricity and thereby access to light and education.
Enabling worldwide economic growth by cost effective reduction of carbon dioxide constraints.

It is a further object of the present invention to enable—simultaneously with and/or alternately to cooking, casu quo as a later add-on step/means—electricity generation from sunlight in a convenient, cost effective manner, especially so at low solar altitudes, by illuminating rocking PV cell modules with sunlight and/or augmented sunlight radiation provided by a tiltable and bendable mirror which is a key means of the present invention.

With the above and other objects in mind, the invention is hereinafter described with reference to embodiments thereof, the novel features of which are particularly pointed out.

Other objects and advantages of the method and apparatus of the present invention will be apparent to those skilled in the art or science casu quo the commerce to which this present invention pertains from the following drawings and detailed description, taken in conjunction with the appended claims.

### BRIEF DESCRIPTION OF DRAWINGS

FIGS. 1, 2C: Show a sectional view and simulated net to food cooking power of a typical prior art hot box type solar cooker, as the lowest solid line curve.

FIGS. 2A, 2B, 2C: Show the method and apparatus of the present invention in a basic embodiment equipped with a tiltable flat upper mirror, also showing attainable net to food cooking power as the highest solid line curve and total power as the broken line curve.

FIGS. 3A, 3B, 3C: Show the method and apparatus of the present invention in an embodiment with a tiltable and bendable upper mirror, also showing attainable net to food cooking power as the solid line curve and total power as the broken line curve.

FIGS. 4A-4L: Show examples of useful basic cooking concepts with progressively improving thermal communication between solar radiation and food.

FIGS. 5A-7H: Show sectional views of preferred embodiments of the method and apparatus of the present invention also showing net to food cooking power attainable without booster mirrors over a solar day at various latitudes in different seasons as solid line curves, total power is shown as broken line curves.

FIGS. 8A-8E: Show examples of the method and apparatus of the present invention in a reduced cost embodiment, showing attainable net to food cooking power in different seasons as solid line curves.

FIGS. 9A-9D: Show examples of the method and apparatus of the present invention in preferred embodiments for cooking soups, heating liquids and/or sterilizing water.

FIGS. 10A-10H: Show examples of the method and apparatus of the present invention in a preferred embodiment for PV electricity generation, also showing PV cell irradiation attainable without booster mirrors over a solar day at various latitudes in different seasons, as solid line curves.

FIG. 11: Shows cooking power attainable with the method and apparatus of the present invention without booster mirrors worldwide at various latitudes in different seasons, net to food cooking power is shown as solid line curves, total power is shown as broken line curves.

FIG. 12: Shows PV cell light irradiation attainable with the method and apparatus of the present invention without booster mirrors worldwide at various latitudes in different seasons, as solid line curves.

FIG. 13: Shows examples of tray-shaped absorbers casu quo cooking trays.

FIGS. 14A, 14B: Show lower cooker cavities with tray-shaped absorbers casu quo flat absorbers.

FIGS. 14C, 14D: Show upper cooker cavities with tray-shaped absorbers casu quo flat absorbers.

FIGS. 15A-15B: Show total cooker cavities with tray-shaped absorbers casu quo flat absorbers.

FIG. 16: Shows total cooker cavity with lower tray-shaped absorber and downward indented upper absorber.

FIGS. 17A-17D: Show examples of hinged, tiltable, bendable mirror, also showing upper profiled guide rail casu quo lower profiled guide rail with mirror holding casu quo mirror drive means and showing optimum bendable mirror tilt angles and bendable mirror compressions as a function of solar altitude angle as and bendable mirror height hₘ.

FIGS. 18A-18I: Show examples of construction casu quo embodiments of half-barrel shaped reflective cavities.

FIGS. 19A-19D: Show examples of embodiments of the method and apparatus of the present invention for PV electricity generation.

FIGS. 20A-20D: Show examples in afternoon orientation of embodiments of halogen light sources useful in the method and apparatus of the present invention.

FIGS. 21A, 21B: Show examples of embodiments for water purification by heating and light irradiating water from above through a light-transparent cover and from below in a light-transparent tray-shaped absorber as shown in FIG. 21A casu quo heating water from below in an opaque tray-shaped absorber as shown in FIG. 21B.

FIG. 22: Shows an example of a preferred embodiment of the method and apparatus of the present invention for simultaneous cooking and PV power generation.

FIGS. 23A-23C: Show examples of an embodiment of the method and apparatus of the present invention equipped with optional booster mirrors.

FIG. 24: Shows an example of a preferred embodiment suitable for windy environments incorporating two upper guide rails supported by a stabilized upper structure.

FIGS. 25A-25E: Show views of a most preferred compact embodiment without upper structure, optimized for simultaneous cooking and electricity generation in one operation casu quo one movement by a bendable mirror of a rocking PV module and furthermore equipped with guide rail plates with punched-in registration numbers intended to qualify the apparatus for accrual of emission credits.

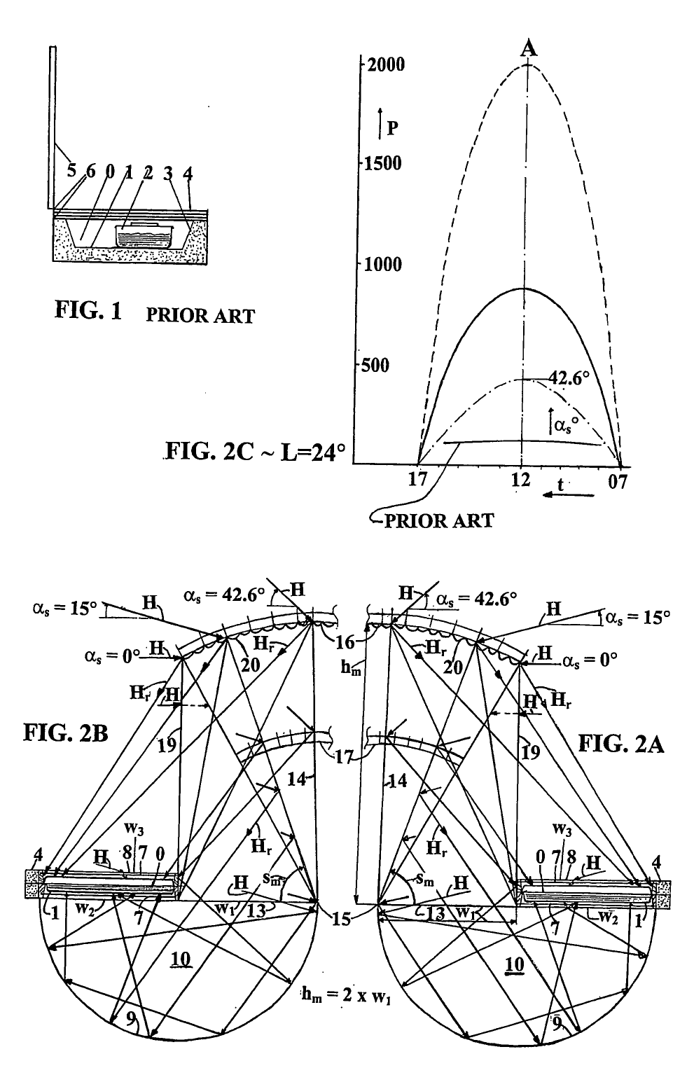

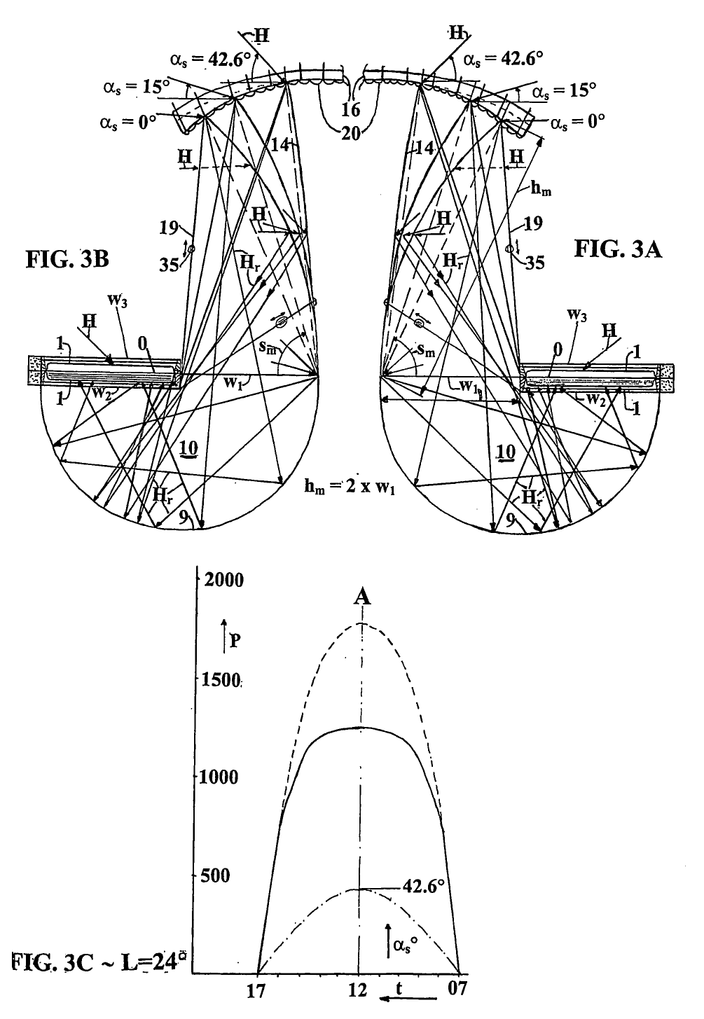

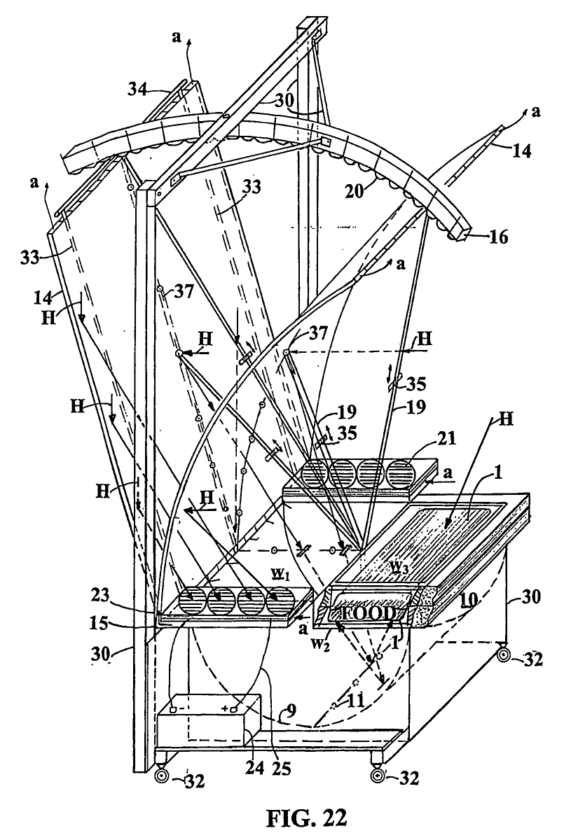

### LEGEND TO FIGS. 2-25

Item No. Brief Description

0 Cooker cavity
1 Absorber, flat casu quo tray-shaped
2 Cooking vessel with food
3 Support frame for absorber 1
4 Insulation of side wall of support frame 3
5 Reflective surface on outer wall of support frame 3 casu quo on vertical walls of concave reflective cavity
6 Reflective surfaces on inner walls of support frame 3
7, 8 Plate, sheet or foil, transparent for light
9 Still-air reflective cavity, half barrel shaped concave reflective wall
10 Still-air reflective cavity, reflective end walls
11 Drain hole
12 Storage rolls for reflective sheet, foil or film (optional)
13 Transparent windows w₁, w₂, w₃ possessing anti-reflective coating on surfaces facing incoming light
14 Tiltable casu quo tiltable and bendable mirror reflector/cooling air chimney for PV modules
15 Hinges
16 Upper guide rail casu quo upper profiled guide rail
17 Lower guide rail casu quo lower profiled guide rail (alternate to 16)
18 Tension rod, tape or wire (alternate to 16)
19 Shadow casting cord, serving as azimuth tracking aid casu quo gnomon in shadow-casting communication with vertical hairline casu quo bulls-eyes line on the mirror surface of mirror/reflector 14 casu quo with horizontal hairline casu quo bulls-eyes line on the upper surface of first window w₁, said cord 19 also serving as support cord for shadow-casting rod casu quo bead 35.
20 Mirror compression profile casu quo manual drive casu quo motorized drive system (optional) for tiltable casu quo tiltable and bendable mirror/reflector 14
21 PV cell module
22 Support ledges for PV cell module 21
23 Flexible connection system for air draft
24 Battery
25 Electrical conduit means between PV module and battery
26 Halogen light sources (optional)
27 Insulating cover possessing reflective surfaces
28 Tiltable booster mirror (optional)
29 Temperature indicator (optional)
30 Support structure
31 Ballast weights for wind stability
32 Castor wheels (optional)
33 Spring rod
34 Connecting rod for guide rail tracking by spring rods
35 Shadow casting rod casu quo shadow casting bead
36 Positioner rod for booster mirror
37 Hairline casu quo bulls-eyes line positioned vertically on mirror 14 casu quo horizontally on first window w₁, serving as aid for azimuth tracking and/or solar altitude tracking through shadow-casting communication with shadow-casting cord 19 and/or shadow-casting beads 35.
38 Hairlines positioned in sundial manner horizontally on first window w₁ and/or positioned vertically on mirror 14 serving, during operation, through shadow-casting communication with cord 19, to indicate degrees off-azimuth φₛ of the apparatus.
39 Cross bar between rocker arms.
40 Rocker arm casu quo pivoted sliding lever.
41 Slot plate on rocker arm.
42 Pivot.
43 Roll on pivot.
44 Shaft between rocker arms.
45 Roll on shaft.
46 Connecting rod.
47 Rocking rack.
48 Guide rail plate, alternate to guide rails 16 and/or 17
49 Handle bar connected to shaft.
50 Grip on handle bar.
51 Dial showing tilt angle of rocker arm casu quo mirror tilt angle.
52 Rope casu quo cord.
53 Pulley.
54 Support for pulley.
55 Gnomon.
56 Insulation on half barrel shaped reflective cavity.
57 Wheels (optional).
58 Windscreen.
   Symbols Meaning
α Absorptivity
αₛ Solar altitude angle
ε Emissivity
ρ Reflectivity
τ Transmisivity
φₛ Solar azimuth angle
θᵢ Angle of incidence
a Air, coolant air
a.m. Ante meridiem, forenoon, morning
A Winter solstice, on December 21 north of equator casu quo on June 21 south of equator
B Spring/autumn equinoxes on March 21 casu quo September 21
C Summer solstice on June 21 north of equator casu quo on December 21 south of equator
Cₘ Bendable mirror compression
Cₚ Bendable mirror compression profile on guide rail
H Solar beam radiation
Hᵣ Reflected solar beam radiation
hₘ Mirror height
I Intensity of radiation in watts per square meter PV module area
Lₙ, Lₛ Latitude, degrees North casu quo South
n Noon
P Power in watts per square meter net cavity area
p.m. Post meridiem, afternoon
r Radius
r_{c} Radius of half-barrel shaped concave reflective cavity
r_{g} Radius of guide rail curvature
rₘ Radius of bendable mirror curvature
sₘ Mirror tilt angle
t Solar time, hours
w Width

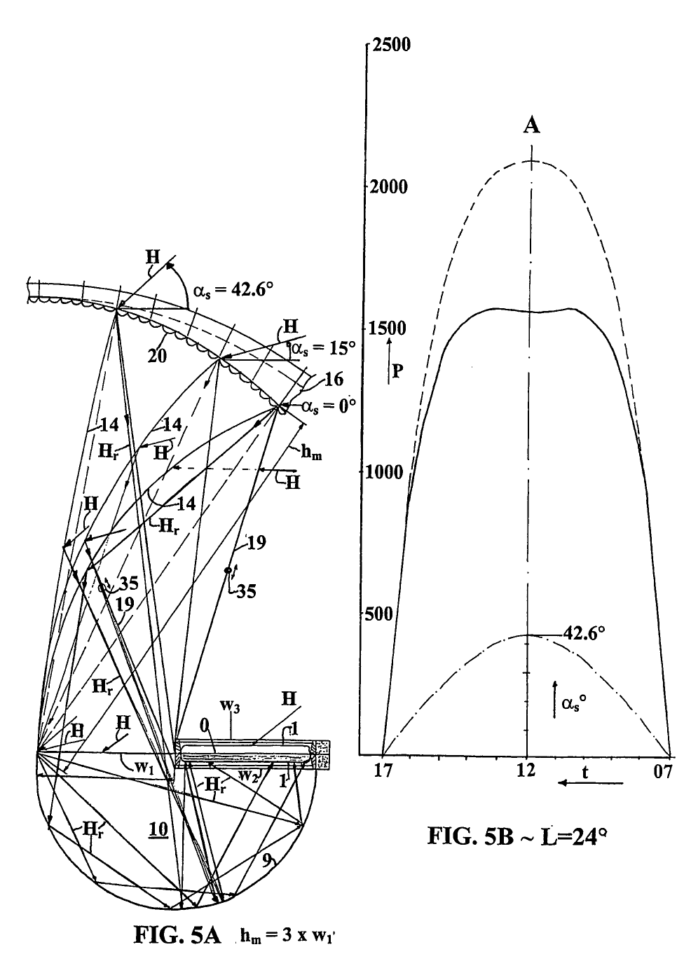

### Legend to FIG. 4

FIG. 4A: teaches cooking food in vessels, heated from below by a flat absorber, cavity top being insulated.

FIG. 4B: teaches cooking food in vessels, heated from below in “au bain-marie” manner by a tray-shaped absorber, cavity top being insulated.

FIG. 4C: teaches cooking food directly in tray-shaped absorber heated from below, cavity top being insulated.

FIG. 4D: teaches cooking food in “steam cooking” manner above boiling water in tray-shaped absorber heated from below, cavity top being insulated.

FIG. 4E: teaches cooking food in vessels heated from below and from above by flat plate absorbers.

FIG. 4F: teaches cooking in vessels heated from below in “au bain-marie” manner by a tray-shaped absorber and from above by a flat plate absorber.

FIG. 4G: teaches cooking food directly in tray-shaped absorber heated by conduction from below and radiantly heated from above by flat plate absorber.

FIG. 4H: teaches cooking food in “steam cooking” manner, food being heated from below by steam from tray-shaped absorber and radiantly heated from above by flat plate absorber.

FIG. 4I: teaches cooking food in vessels, heated in “au bain-marie” manner from below by a tray-shaped absorber and radiantly heated from above by a tray-shaped absorber.

FIG. 4J: teaches cooking food, directly in tray-shaped absorber, food being heated by conduction from below and radiantly from above by tray-shaped absorbers, food temperature being made visible by a temperature indicator casu quo a thermometer.

FIG. 4K: teaches cooking food directly in and between tray-shaped absorbers heated by conduction from below and from above by tray-shaped absorbers.

FIG. 4L: teaches cooking food in “hamburger” manner directly between tray-shaped absorbers, heated by conduction from below and from above by tray-shaped absorbers.

### Definition of Terms

The term “mirror tilt angle” sₘ is the angle between the horizontal plane and the mirror surface facing the sun.

The term “angle of incidence” θᵢ is the angle between the light rays and the surface normal.

The term “solar altitude angle αₛ is the angle between the sun's rays and the horizontal plane.

The term “solar azimuth angle” φₛ is the angle of the sun's rays measured in the horizontal plane from due south, westward being designated as positive. For the southern hemisphere it is measured from due north, eastward positive.

The term “incident” is intended to mean: falling on or falling upon.

The term “spectrally selective surfaces” is intended to mean: surfaces having high absorption properties (α) for light radiation in wavelengths of the full solar spectrum combined with low heat radiation casu quo heat emission properties (ε) in wavelengths of the infrared spectrum.

The term “sunny side” is intended to mean: the side casu quo the surface receiving casu quo seeing incoming light.

The term “casu quo” is intended to mean: or, as the case may be.

The term “au bain-marie” is intended to mean: standing on casu quo in a layer of a liquid.

The term “convex” is intended to mean: outwardly curved casu quo bulging out.

The term “concave” is intended to mean: inwardly curved casu quo hollow.

The term “cavity” is intended to mean: a hollow space.

The term “net cavity area” is intended to mean: the area in square meters of the cross section in the horizontal plane of said cooker cavity.

### MODES FOR CARRYING OUT THE INVENTION BASIC APPARATUS USEFUL IN THE METHOD

Referring now to FIG. 2A/2B the method and apparatus of the present invention is shown in a first useful basic conceptual design in forenoon and afternoon orientation.

A cooker cavity 0, having well-insulated side walls 4, is provided with a concave tray 1 pressed into a desired shape and dimensions from a sheet of heat conducting heat resistant metal coated on the convex casu quo the illuminated side with a heat resistant spectrally selective coating, capable of converting light energy to heat. For protection of said selective coating and for reduction of heat losses to the ambient a sheet casu quo plate 7 of a heat resistant material highly transparent for sunlight, such as for example a fluorocarbon such as Teflon FEP® or a tempered low-iron glass with an anti-reflective coating is provided and positioned under said coating. A second sheet casu quo plate 8 of said transparent material may be installed under said sheet casu quo plate 7 for enhanced protection and further reduction of heat loss.

Said cooker cavity is positioned, with the spectrally selective coating downward, facing the reflected light into casu quo onto a still-air concave reflective cavity 9 having the shape of a half-barrel with a horizontal axis of rotation. The concave walls 9 of said half-barrel are highly reflective and are facing the underside of said cooker cavity. The two end walls 10 of said half-barrel perpendicular to said axis of rotation of the half-barrel are highly reflective and may be flat, the curved part of said half-barrel parallel to its axis of rotation is cylindrical and may be a continuous curve or made up of a sequence of flat and/or curved segments approximating any desired shape of for example circular, catenary, parabolic, elliptic or polygonal shape or any combination of said curved shapes and flat shapes. Said desired shape is preferably made partly or wholly of a flexible reflective sheet casu quo foil material, enabling variable shape casu quo curvature optimized for desired cooking casu quo heating operations.

Said still-air concave reflective cavity 9 is located partly under said cooker cavity 0, partly extending sideways therefrom and terminating as an approximately horizontal light admitting aperture w₁, hereinafter called first window, covered with a plate or sheet 13 of a material highly transparent to sunlight. Above said first window w₁ is provided a hinged tiltable mirror/reflector 14 facing the sun, tiltable on hinges 15, reflecting sunlight to said first window w₁ and to the top of the cooker, said mirror having a height approximately equal to the diameter of said half-barrel. The optimum light collecting tilt angle of said hinged tiltable mirror facing the sun in the flat shape can be established for example by means of an upper guide rail 16 or a lower guide rail 17 and is governed by the relationship sₘ=60°+⅔ as casu quo the mirror tilt angle above the horizontal plane is equal to sixty degrees plus two-thirds of αₛ wherein sₘ is the mirror tilt angle and wherein αₛ is the solar altitude angle above the horizontal plane. αₛ depends on the time of the day, the day of the year and the latitude. At sunrise and sunset the optimum mirror tilt angle is 60° for said mirror in the flat shape facing the sun.

A cover cavity 0, conveniently a duplicate of the cooker cavity is provided and positioned in upside down arrangement above the cooker cavity with the convex side of said tray 1, the spectrally selective coated side upward facing the light. For protection of said selective coating and for reduction of heat losses to the ambient a sheet casu quo plate 7 of a heat resistant material highly transparent for sunlight, such as for example a fluorocarbon like Teflon FEP®, or a tempered low-iron glass with an anti-reflective coating, is provided and positioned above said selective coating. A second sheet casu quo plate 8 of said transparent material may be installed above said sheet casu quo plate 7 for enhanced protection and further reduction of heat loss. The space enclosed between said cover cavity 0 and said cooker cavity 0 is the total cooker cavity 0 and may have a total height that admits cooking vessels.

For cooking operations, the apparatus of the present invention is oriented to face the sun, cord 19 casting its shadow on a vertical hairline on the mirror surface of mirror 14. The tiltable mirror facing the sun is adjusted to the solar altitude angle, for example by means of a guide rail 16. At a solar altitude angle αₛ of 15° the optimum mirror tilt angle is 70°, at αₛ of 30° the optimum mirror tilt angle is 80°, at αₛ of 45° the optimum mirror tilt angle is 90° and so on until the αₛ is 90° and the optimum mirror tilt angle is 120° from whereon the mirror tilt angle is reduced as the sun goes lower.

Light is collected by the tiltable mirror and reflected through said first window w₁ via a second window w₂ to the underside of the cooker cavity where it is converted to heat by the selective coating and conducted to the food positioned on the tray. At low angles of solar altitude as said reflected light is the major source of cooking power. Part of the light collected by the tiltable mirror is reflected through the light aperture area w₃, hereinafter called third window, to the spectrally selective coated side of the cover casu quo the top of the cooker cavity where it is converted to heat which is conducted through the cover tray and radiated to the food below the cover tray.

As the sun rises and the solar altitude angle αₛ increases, more and more direct radiation is transmitted through said first window w₁ via said second window w₂ to the underside of the cooker cavity and through said third window w₃ to the top of the cooker cavity.

Simulated net to food cooking power of said basic apparatus as a function of the solar altitude αₛ at the time of the day for 21 December, the winter solstice at about 24° N is shown, as the highest solid line curve in FIG. 2C. Total power is shown as the broken line curve, and is about 2,000 watts/m² net cavity aperture area, a 50 cm×50 cm cooker cavity, equipped with a 50 cm×50 cm first, second and third window having a transmissivity of 92% and a one meter high by one half meter wide mirror having a reflectivity of 90% in flat shape, provides a net to food peak power of about 500 watts for fast warm-up, but a sustainable net to food cooking power of 1,000 watts or more per square meter net cavity area cannot be reached.

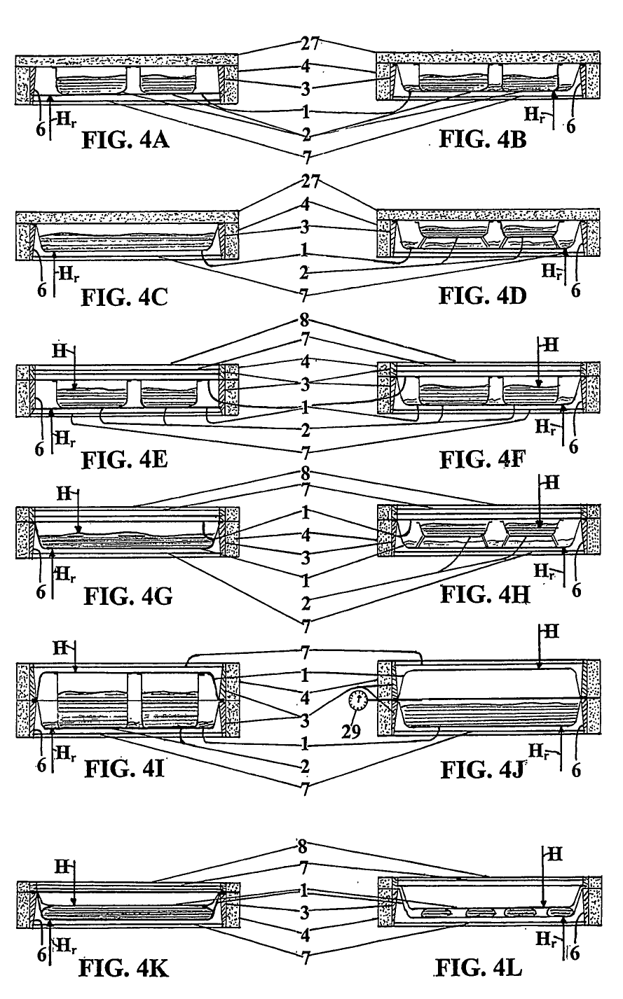

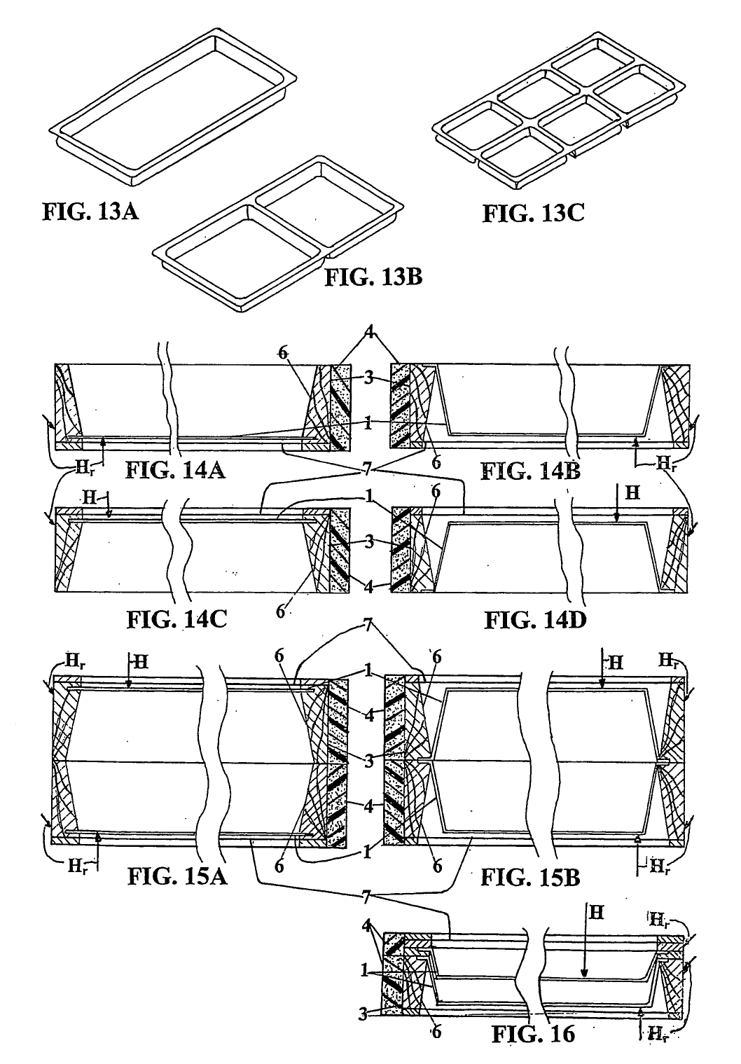

Net to food cooking power is augmented considerably, especially so at low solar altitudes prevailing in mornings, afternoons, in winter or at higher latitudes, by bending said tiltable mirror, for example by compressing said tiltable mirror with a profiled upper guide rail 16 or a tension rod, tape or wire 18 combined with a profiled lower guide rail 17, as shown in FIGS. 3A/3B in forenoon and afternoon orientation and in FIGS. 17A/17B. By optimizing the bending casu quo the curvature of said tiltable mirror in combination with its tilt angle it becomes a practical possibility to reflectively direct a major part or all of sunlight acquired by said tiltable bent mirror onto and through said first window w₁, with more favorable angles of light incidence to the underside of said cooker cavity.

Simulated net to food cooking power of said basic apparatus acquiring sunlight with said tiltable mirror in bent shape as a function of the solar altitude αₛ at the time of the day for December 21, the winter solstice at about 24°N, is shown as the solid line curve in FIG. 3C. Peak power for fast warm-up is about 1,750 watts/m² cooker box aperture area. Sustainable net to food cooking power to the cooker cavity bottom is augmented by more than 40 (forty) percent from about 870 watts/m² to about 1,230 watts/m² net cavity area. A target sustainable cooking power of 1,000 watts/m² to said cooker cavity bottom can be made available for about 6 (six) hours per day, a 50 cm by 50 cm cooker cavity equipped with a 50 cm by 50 cm first window and a 50 cm wide by 1 meter high mirror in optimum bent shape and tilt angle being capable of providing net to food sustainable bottom cooking power of 250 watts or more for about 6 (six) hours, e.g. from 09.00 to 15.00 hours.

Upon completion of cooking the food can conveniently be served in the cooking cavity and kept warm during the meal by placing an insulating lid or board over the cavity with food.

As the cooker cavity is removed, the cover cavity with its tray can take over the cooking work by positioning the cover cavity with the convex side downward into casu quo onto said still-air concave reflective cavity 9. The next meal or dish can then be cooked, either by placing a third cover cavity or by placing an insulating lid or board over the food while 5 cooking proceeds on heat supplied from below only. For professional all-day cooking it is convenient to provide a plurality of cooking cavities with different trays taking turns in cooking/heating a variety of dishes and/or beverages. A high degree of versatility can be provided through the use of special trays and/or inserts for particular cooking operations.

Turning now to FIGS. 425 an overview is shown of several embodiments casu quo examples of the method and apparatus of the present invention useful to augment convenience of cooking on light by increasing net to food heating power from the energy contained in available solar radiation. A novel and crucial inventive feature of the present invention resides in a) creating substantially improved light and thermal communication especially at small solar altitude angles casu quo when the sun is low, between the energy contained in solar radiation available to the cooker area and the food to be cooked casu quo the beverage to be heated, casu quo to a PV cell module area and b) in reducing heat losses drastically, especially so from the top and bottom of the cooker cavity.

Regarding a): Surprisingly I have found that solar conductive food heating from below is far more effective than solar radiant food heating from above. This surprising discovery may be explained in part because in a hot box type light cooker of the present invention reflectively directed solar radiation from below reaches said cooker tray 1 casu quo absorber 1 unobstructed and uses the full area of the absorber 1, which conducts the heat directly to the food resting on it. Furthermore, because the absorber is located in casu quo on a still-air cavity 9 above the ambient, the buoyancy of any heated air under the absorber 1 prevents convective heat carrying currents downwards from the absorber 1. Substantially improved thermal communication between the food to be cooked casu quo the beverage to be heated and available solar radiation has thus been accomplished by augmenting net to food heating power from the underside of said cooker casu quo the underside of said food.

Also surprisingly I have found that by providing a spectrally selective coating on the underside of said cooker tray 1 in combination with one or more convection-suppressing sheets or plates 7, 8 of a light transparent material positioned under said cooker tray heat losses are reduced and net to food cooking power increased.

Surprisingly I have further found that by positioning said cooker tray 1 with said transparent sheet 7 in or on a still-air concave reflective cavity 9 heat losses are further reduced to a very low level. Similarly hot cooked food in said cooker tray stays hot longer if said tray is placed on a place mat of reflective material.

More surprisingly I have found that by fabricating the curved part of said half-barrel shaped concave reflective cavity 9 from a flexible material, such as for example an aluminized polyester film, the curvature and the position of the nadir casu quo the lowest point of said curve can be varied, both vertically and horizontally, thereby enabling optimum transfer of sunlight from said first window w₁, said sunlight reaching the underside of said cooker cavity at optimum angles of incidence for conversion of light to heat by said selective surface.

Still more surprisingly I have found that especially at low solar altitudes, by bending said hinged tiltable mirror 14 located above said first window w₁ to a mirror curvature which varies with the mirror tilt angle sₘ and the solar altitude angle αₛ, all the light that a flat mirror would reflect to said third window w₃, can be reflected in an optimum manner by said bent mirror 14 to a PV cell module positioned under said mirror 14 or to said first window w₁ and onwards via concave reflective cavity 9 to the underside of the cooker cavity. For example, in said basic apparatus, by said bending of said tiltable mirror, long duration bottom cooking power is increased by about 40% while peak cooking power is reduced by only about 12%. Improved light communication between available solar radiation and said PV cell module or the spectrally selective coating on the underside of the cooker is accomplished, especially so when the sun is low, in winter, at higher latitudes and worldwide at sunrise and sunset, enabling fast build-up of high levels of electric power and/or cooking power.

Regarding b):

In prior art hot box type solar cookers the major heat loss is through the light admitting aperture casu quo window w₃ on top of the cooker cavity. Surprisingly I have found that by positioning a metal sheet 1, coated on at least one side with said spectrally selective coating, said coating facing the sunlight, under said window above the food, casu quo the cavity, loss of heat through the top of the cooker cavity can be reduced by 50% or more, especially so at higher food temperatures.

More surprisingly I have found that large thermal efficiency losses caused by poor heat conducting contact between various cooking vessel bottoms and the much hotter absorber plates characterizing prior art hot box type solar cookers can be avoided by using said bottom tray 1, heated by light from below directly as a large area evenly heated cooking tray.

### Novel Components Useful in the Method and Apparatus

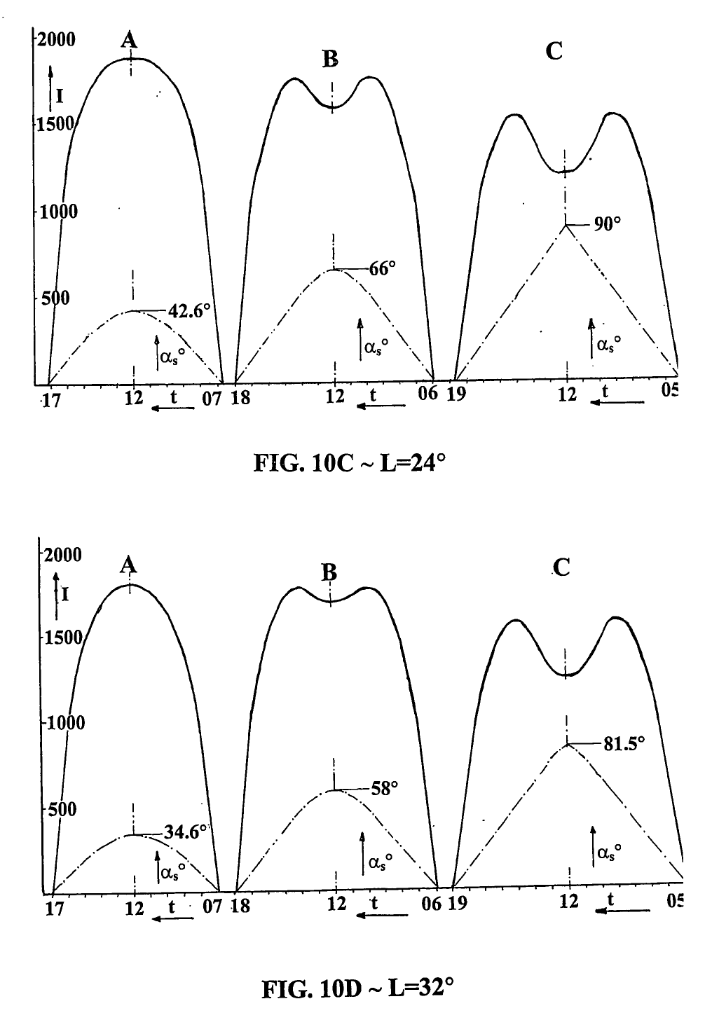

As a first novel component in the present invention is introduced a first heat conducting metal plate 1 of a metal quality that is resistant to corrosion by both the ambient and the cooker cavity atmospheres. On at least one surface, the surface facing sunlight when in use, of said first metal plate 1, a spectrally selective surface is provided. Said spectrally selective surface is characterized by being an excellent absorber (α) for incoming full spectrum solar energy radiation and being a poor emitter (ε) of infrared heat radiation. Said first metal plate 1 thus functions as a new, one way spontaneous converter of solar radiation to heat which is instantly conducted and put to use to heat food at only minor back-radiation of heat energy to the ambient. Said first metal plate 1 serves as the solar energy collecting approximately horizontal underside 1 of the cavity 0 of the well insulated hot box type light cooker of the present invention. Said first metal plate 1 may be flat, with metal cooking vessels placed upon the plate, or formed in the shape of a tray 1, as shown in FIG. 13, or a vessel by, for example, a well-known deep drawing operation under a press. If formed into a tray 1 said first metal plate advantageously functions also as the cavity of the cooker, cooking vessels may be placed upon the tray bottom. In a preferred cooking manner of the “au bain-marie” type, having excellent thermal communication, a thin layer of water is provided on the bottom of the tray. Said thin layer of water next to and under the cooking vessel continuously vaporizes and condenses, transferring latent heat to the vessel bottom and vessel side. During warm-up said water conducts heat to said vessels. In addition, being an excellent infrared radiator with high emissivity in the infrared wavelengths, said water radiates heat upwards to the cylindrical part of said vessels. The rims of said cooking vessels are to be flat, so as to maximize the heat conduction contact area between said vessel rims and a heat conducting plate located above said vessel rims. In another, more preferred cooking manner without cooking vessels, said first metal plate in the shape of a tray I of cavity dimensions directly receives the food to be cooked on the bottom of said tray 1 in loose form or in a cooking bag. Intimate thermal communication between the food to be cooked and the energy source is thereby created. Likewise said tray 1 may function as a simmering or frying pan, or other cooking variants such as for example “Chinese wok” stir frying operations. In yet another more preferred cooking manner without cooking vessels, and enabling superior thermal communication between the food to be cooked and the solar energy driven heat source, the tray bottom 1, a thin layer of water is poured on the bottom of the tray 1. Above said layer of water a sieve tray is placed containing foods, such as rice, noodles, lintels, vegetables, fish, meats for steaming casu quo steam cooking. During warm-up and cooking said water supplies latent heat (steam) to said food. At the end of the day said water may serve as a reservoir of heat for extended cooking and/or warm-keeping of foods.

As a second novel component in the present invention is introduced a first sheet 7 of a material transparent to sunlight. Said material may be low-iron glass having an anti-reflective coating or a heat resistant polymer having a high light transmittance and a low refractive index. Said first transparent sheet is installed approximately horizontally below said tray and attached to said cooker cavity at a distance of approximately 10 (ten) to 20 (twenty) millimeters below said first metal sheet 1 casu quo metal tray 1. Useful functions of said first transparent sheet 7 comprise:
a) protecting said spectrally selective coating on said metal sheet 1;
b) suppression of any air currents between the ambient and said first heat conducting metal sheet casu quo tray 1.

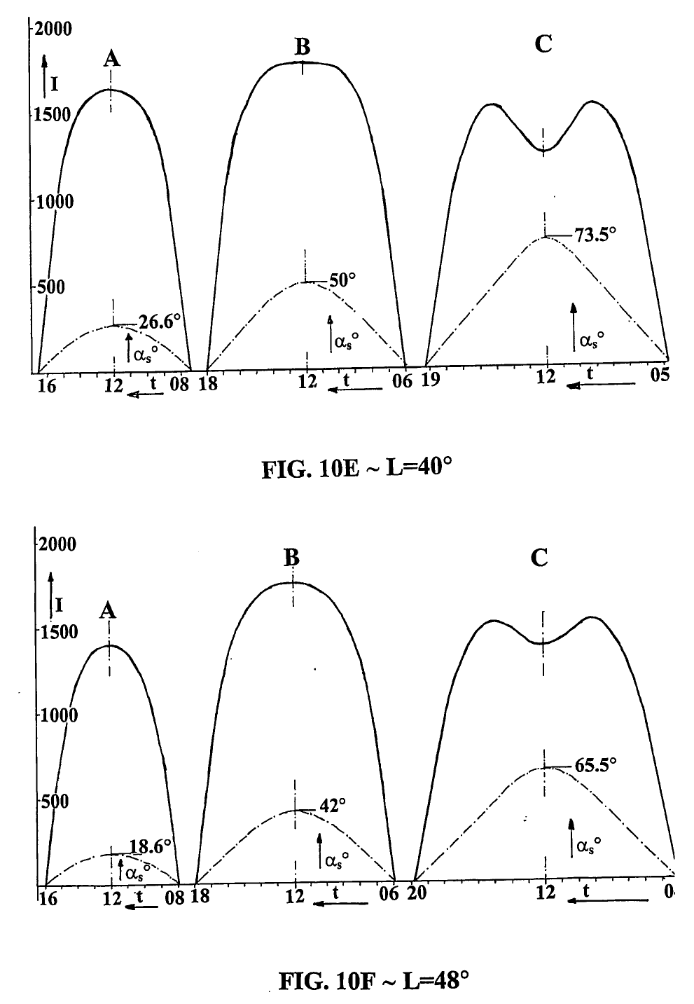

As a third novel component in the present invention is provided a well-insulated movable cavity 0, as shown in FIG. 14A-B, accommodating said first absorber tray 1. Said insulation 4 is preferably a combination of a moisture-proof high temperature insulation closest to the tray, backed-up by moisture-proof highly insulating medium temperature insulation of for example poly-isocyanurate, phenolic or polyurethane foam type encased in an outer enclosure of a suitable low cost material such as for example wood or plywood, alternatively a foam-aluminum sandwich or a foam-steel sandwich. Reflective surfaces are advantageously provided on outer wall 5 of said enclosure, exposed to reflected radiation and on all inner walls 6. Depths of said cavity can be tailored to particular cooking operations to be performed, for optimal results. Preferred cavity depths are approximately:
a) for cooking directly in trays: approximately 10 to 100 millimeters
b) for cooking in vessels: approximately 10 to 200 millimeters
   Said cavity 0 may be a single cavity casu quo a plurality of smaller cavities for individual eaters.

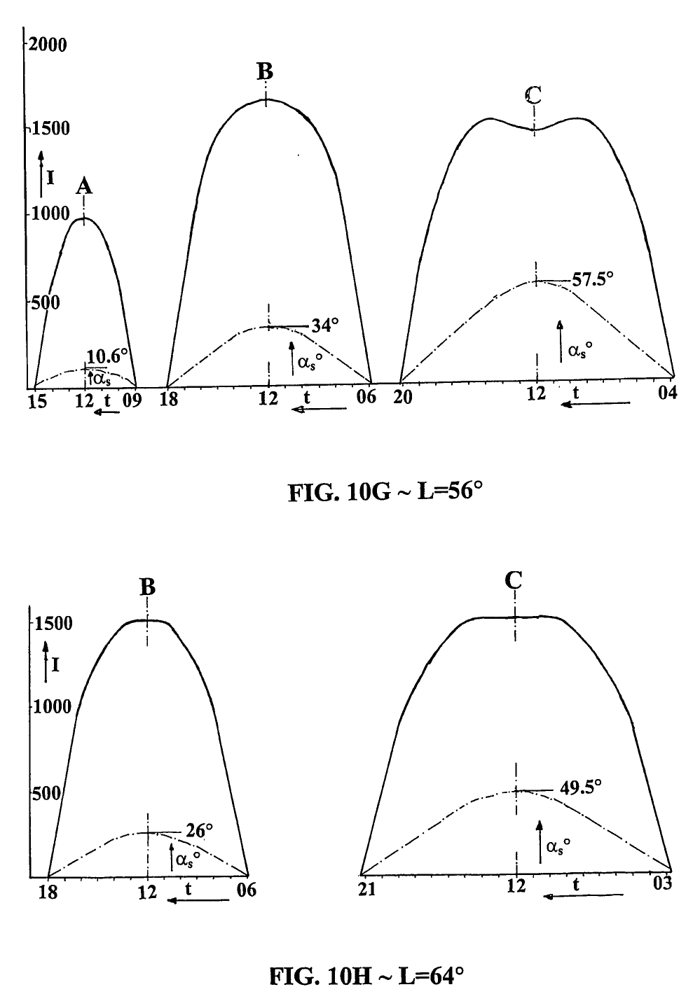

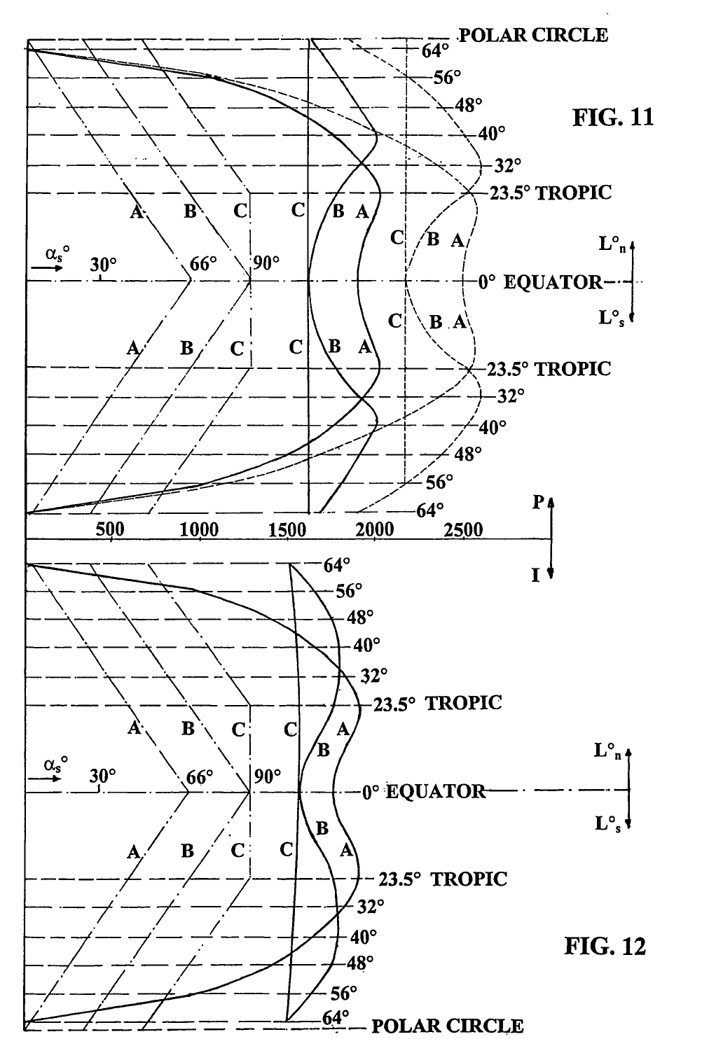

Turning the attention now to the topside of the hot box type light cooker of the present invention, a fourth novel component in the present invention is introduced: a second heat conducting metal plate 1, having the same corrosion resistant quality as said first heat conducting metal plate 1 and provided with the same said spectrally selective coating on at least one surface, the surface facing incoming sunlight when in use, is provided. Said second heat conducting metal plate 1 is located in an approximately horizontal position immediately above the cavity 0 of said hot box type light cooker with the spectrally selective coating facing upwards to the light. Said second metal plate 1 thus performs in the same manner as said first metal plate 1 as a one way converter of incoming solar energy, spontaneously converted to heat energy, which is instantly, with minimal thermal resistance through the thin metal sheet 1, conducted to cooking vessels positioned directly under and in pressed, heat conducting communication with said second metal plate 1. Said second metal plate 1 serves simultaneously as the underside of an openable cover located above said cooker cavity 0, and as a common flat lid for the cooking vessels. Said second metal plate 1 may be flat or advantageously indented upwards, thus acquiring the shape of an inverted casu quo upside down cooking tray, as shown in FIGS. 14C-D. A heat resistant paint with a high emissivity (ε) such as for example black alkyd or epoxy enamel, is advantageously provided on the underside of said second metal sheet, as a heat radiator for grill-type cooking. In operation, upper plus lower cavity make up a total cooker cavity 0, as shown in FIGS. 15A/15B. In certain cooking operations without cooking vessels, using a cavity shaped first metal tray 1, it may be advantageous to use a downward indented version of said second metal plate 1, as shown in FIG. 16. Once the food has been heaped on said first metal tray 1, either loose casu quo enclosed in a cooking bag, said covering cavity incorporating said downward indented version of said second metal plate 1, is lowered thereby pressing the indented part of said second metal plate 1 onto and/or slightly into the food to be cooked. In so doing creating highly effective intimate full plate area heat conducting communication from above and from below between the food to be cooked and solar energy from above and from below.

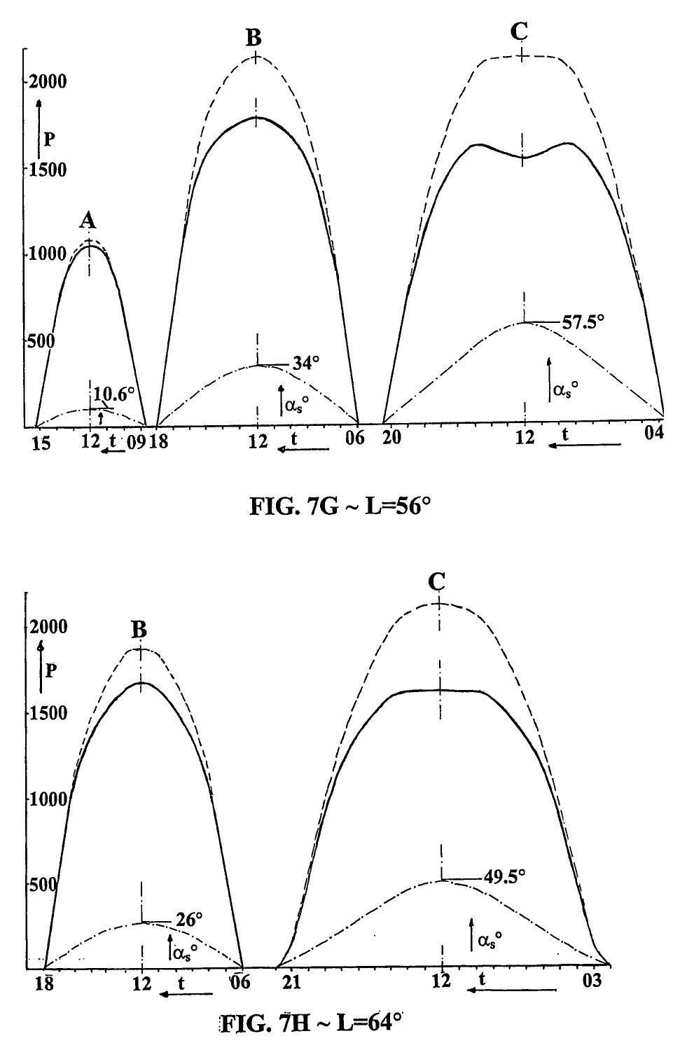

As a fifth novel component in the present invention is introduced a hinged, tiltable flat mirror 14 which is bendable like a large flat spring having its center of curvature approximately on a horizontal plane at the level of said hinges 15, as shown in FIGS. 17A/17B. The degree of bending of said mirror 14 casu quo said mirrors curvature casu quo radius r is varied during a solar day, approximately according to the relationship rₘ=hₘ/2 sine (90°−sₘ°) following said mirrors tilt angle sₘ, following solar altitude angle αₛ, for an optimum harvest of sunlight, reflected onto said PV cell module 21 casu quo onto and through said first window w₁ and onwards via concave reflective cavity 9 to the underside 1 of the cooker cavity 0. In operation, at sunrise, said bendable mirror is positioned to face the sun, for example, with the aid of an azimuth tracking aid in the embodiment of a shadow-casting cord or string casu quo an elastic rubber cord 19 installed between a center point at the edge of w₁ and the center point at the top edge of said bendable mirror 14. Said shadow-casting cord 19 to cast its shadow, as shown, for example, in FIGS. 9, 19, 22 and 23, on a vertical center line casu quo a hairline casu quo a bulls-eyes line positioned on the mirror surface of said bendable mirror 14 and/or on a horizontal hairline casu quo bulls-eyes line on the upper surface of said first window w₁. Optimum bending casu quo compression of said bendable mirror 14 is provided by said profiled guide rail 16, 17 approximately according to the relationship:

$$mirror compression {C}_{m} = {h}_{m} ⨯ [ \frac{.01744 ( {90}^{∘} - {s}_{m}^{∘} )}{sine ( {90}^{∘} - {s}_{m}^{∘} )} - 1 ]$$

by directing the mirror from its flat starting shape under a profiled guide rail 16, possessing a mirror compression profile Cₚ, as shown in FIG. 17A/17B, which compresses said mirror to its first, most curved shape of the day. For a one meter high mirror, as shown in FIG. 17A, illuminating a half-meter wide first window w₁ casu quo PV cell module 21 of the same width, said first compression is about 4.6% (46 millimeter) at a corresponding mirror tilt angle of 60°, facing the eastern sun. As the solar altitude angle αₛ increases over the morning, the bendable mirror proceeds under the guide rail to larger mirror tilt angles sₘ approximately according to the relationship sₘ°≅60°+0.42×αₛ° and to progressively less mirror curvature casu quo less mirror compression, for example at a mirror tilt angle of 70°, said compression is reduced to about 2% (20 millimeter). At a mirror tilt angle of 80°, said compression is reduced to about 0.5% (5 millimeter). The mirror position thus becomes more upright and the mirror springs back to a less curved shape. At a mirror tilt angle of approximately 85° corresponding to a solar altitude angle αₛ of approximately 60°, the mirror has sprung back to its original flat shape. In the sunbelt, where the solar altitude angle may reach about 90°, a 1 m high mirror continues (flat) following the guide rail approximately according to the relationship sₘ°≅85°+0.77×(αₛ°−60°) until it reaches its maximum tilt angle of approximately 108° for cooking casu quo 112° for PV generation at noon facing the southern sun casu quo the northern sun. Said apparatus is then positioned to face and follow the sun in westerly direction and said mirror is made to follow said guide rail, initially in flat shape, until a tilt angle of 85°, thereafter compressed to a progressively more curved shape until at 60° mirror tilt angle, said 1 m high mirror reaches the second most compressed and most curved shape of the day, at sunset. Said mirror is thereupon released from said guide rail and left flat overnight in approximately horizontal position, covering and protecting the apparatus. At 24° North latitude on December 21, the winter solstice, the maximum solar altitude angle α° is 42.6°, at noon, optimum mirror tilt angle at noon is about 78° and the optimum mirror track is from 60° at sunrise to 78° at noon and then back to 60° at sunset, the mirror remaining curved, albeit with variable curvature from sunrise to sunset. For a 1.5 m high mirror, as shown in FIG. 17B, illuminating a half meter wide first window w₁ casu quo PV cell module 21 of the same width, the solar day starts with a mirror tilt angle of about 55° at a mirror compression of about 6.4% (96 millimeter), the mirror then proceeds in bent shape approximately according to the relationship sₘ°≅55°+0.43×αₛ° till a mirror tilt angle of about 85°, corresponding to a solar altitude angle of about 70°, then onwards in flat shape approximately according to the relationship sₘ°≅85°+0.95×(αₛ°−70°) till a tilt angle of about 104° for cooking casu quo 1070 for PV generation corresponding to a maximum solar altitude angle of about 90° at noon in the sunbelt. Said apparatus is then positioned to face and follow the sun in westerly direction. Guide rails and their mirror compression profiles are optimized and made convenient for use in different seasons and their latitudes of destination. Mirror tilting and bending casu quo azimuth tracking of the apparatus may be by manual positioning, alternatively by a pre-programmed spring-driven or electrically driven mini-motor attached to said mirror casu quo said guide rails and tracking said mirror guide rails.

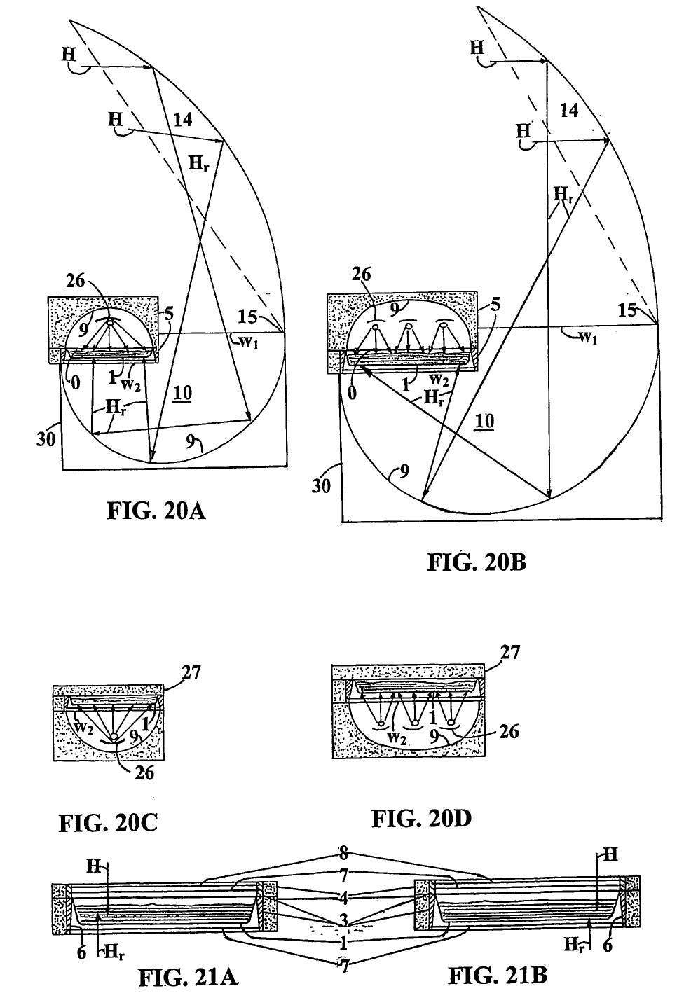

Said manual positioning is made convenient by providing one or more shadow-casting rods casu quo shadow-casting beads 35, hereinafter called shadow-casters. Said shadow-casters 35 are made of a non-scratching material such as, for example, rubber or a polymer, and installed in sliding arrangement on said shadow-casting cords 19 in such a manner that said shadow-casters are maintained in a horizontal position on said cords, with said shadow-casters longest dimension in parallel to said hinge line of said tiltable casu quo tiltable and bendable mirror. Said shadow-casting cords 19 are installed between suitable points on the surface casu quo the upper edge of said mirror 14 and suitable points located on the meeting line where said window w₁ casu quo said PV cell module meets said second window w₂. Said shadow-casters serve to obstruct light reflected by said mirror and are to cast their shadow lines on the surface of said PV cell module casu quo on the surface of said first window at about said meeting line between said PV cell module casu quo said first window and said second window. Visibility of said shadow lines can be improved by momentary hand shading of incoming direct (non-reflected) light. For example, shadow-casters communicating with said mirror surface at about half mirror height result in reflected light from the upper half of said mirror being directed onto said PV cell module casu quo onto and through said first window. Similarly shadow-casters communicating with said mirror surface at about one quarter height result in reflected light from the upper three quarters of said mirror surface being directed onto said PV cell module casu quo onto and through said first window. Said bendable mirror is characterized in operation by its ability to accommodate large ranges of solar altitude angles as shown in FIGS. 17C and 17D. For example, at a ratio of mirror height hₘ to first window width w₁ of 3/1 said bent mirror positioned at 75° mirror tilt angle sₘ can accommodate a range of solar altitude angles αₛ from about 33° to about 45°, which is more than the solar altitude path between 10 am. (34.3°) via 12 noon (42.6°) to 2 p.m. (34.3°) on the winter solstice day at 24° latitude, thereby enabling the cooking of several hot lunches without a change of position of said bendable mirror on said guide rail. For PV electric power generation said mirror 14 is advantageously fabricated using a multi-channel extruded double or triple walled polymer cardboard and installed with said multiple channels in upward direction, as shown in FIG. 21, functioning as chimneys providing draft for air, warmed-up after cooling the underside of said PV cell modules positioned on ridges under and/or sideways from said mirror 14. Said multi-channel extruded polymer cardboard may have its own resilience, alternatively one or more spring steel rods casu quo glass fiber reinforced polyester or epoxy spring rods 33 may be inserted in said extruded channels in order to provide and maintain long-lasting resilience of said bendable mirror. A horizontal connecting rod 34 may be attached to said spring rods for long term wear resistant, accurate guide rail tracking.

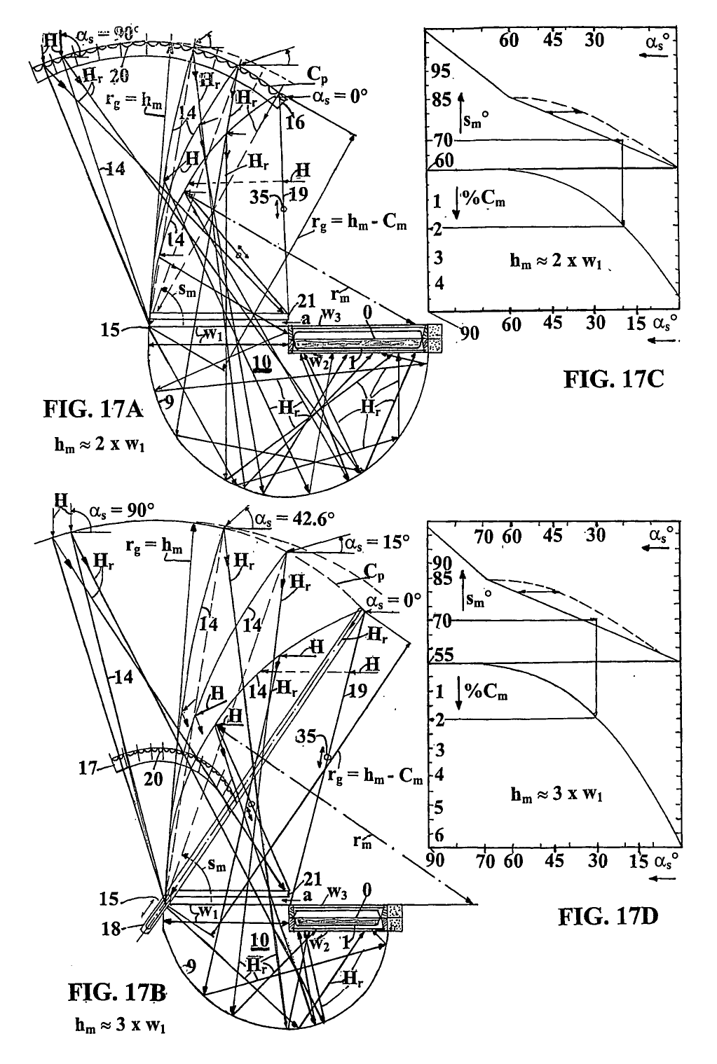

A sixth novel component is introduced for the construction of said half-barrel shaped concave reflective cavity 9, as shown in FIGS. 18A-18E, in the form of a flexible curved mirror of variable shape or curvature that may be circular, catenary, parabolic, elliptic or polygonal, preferably having their center of curvature on or slightly to the right of the meeting line of said first and second window. The shape, the curvature, the depth, and the location of the nadir casu quo the lowest point of said flexible, curved mirror are adjustable, both vertically and horizontally as a function of window transmissivity and/or mirror reflectivity for optimization of light transfer from said bendable mirror via said first window w₁, enabling the most favorable angles of light incidence to the underside of the cooker cavity at various latitudes and solar altitude angles, deeper cavities reducing reflections and improving said angles of incidence. Said mirror may be flexible, installed in half-barrel shape concave curvature by hanging it from two sides parallel to the axis of rotation of said half-barrel shaped concave reflective cavity and provided with drain holes in the nadir line for draining-off unwanted incursions from rain, food spills and the like. In a preferred embodiment, as shown in FIGS. 18F-18J, two rolls are provided, parallel to said axis of rotation, on each side of said half-barrel shaped concave reflective cavity to be. On each roll, part of the reflective sheet material is rolled. The rolls are installed at both ends of said reflective concave cavity to be and the flexible sheet mirror material is unwound and lowered to form a concave reflective cavity of desired shape, curvature and location of the nadir. Alternatively said mirror sheet material is placed on both rolls as one endless band, with the reflective side on the outside. Said preferred embodiments can provide a perfectly clean flexible curved mirror at all times, any incursion of dust, rain, food spills and the like can be cleaned off conveniently by rolling-on of the flexible mirror, wiping clean any unclean section as it moves over a roll.

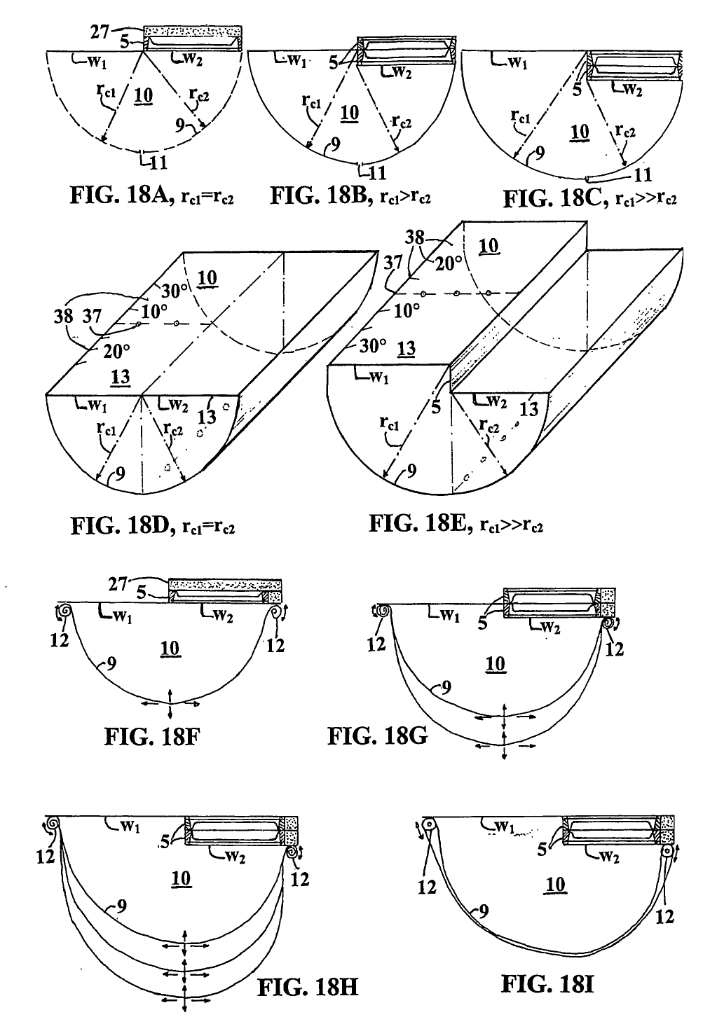

A seventh novel component is introduced for generating electricity by PV cells in the form of PV cell modules 21 positioned in approximately horizontal position, as shown in FIG. 519A, casu quo vertical position under and/or sideways from said bendable mirror 14, as shown in FIG. 19D. The electricity delivered by said PV cell module may be used to charge a battery. Said electricity generation may be positioned when the apparatus is not used for cooking or simultaneous with cooking whenever too much cooking power is available. Electricity generation may also be a continuous operation, either as part of or an attachment to the apparatus, as shown in FIG. 19B, or as a stand-alone embodiment, as shown in FIG. 19C.

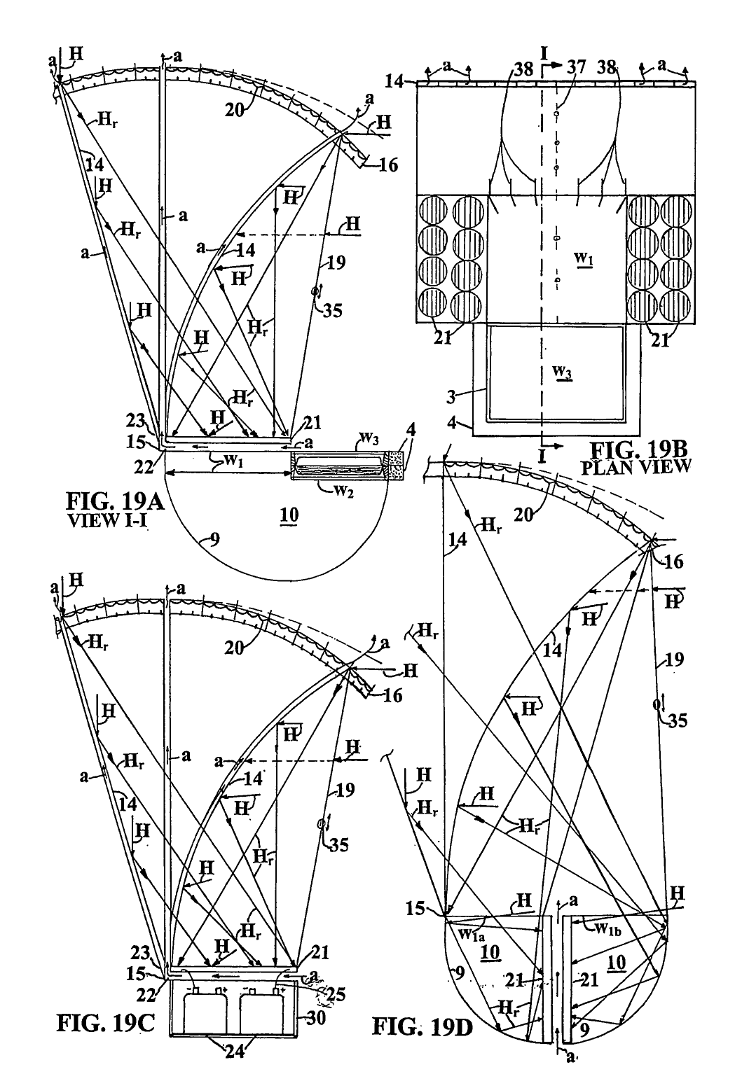

An eighth novel component is introduced in the form of a halogen light source 26, installed in an insulated, reflective box or a support structure that can be positioned above said cooker cavity, as shown in FIGS. 20A/20B, casu quo under said cooker cavity, covered with an insulating board as shown in FIGS. 20C/20D, for cooking operations when sunlight is not available casu quo marginal and electricity can be made available, for example, from said battery or from other sources.

As other low cost, but very useful novel components are introduced shadow-casting cords 19 serving as azimuth tracking aids through shadow-casting communication with hair lines casu quo bulls-eyes lines 37 positioned vertically on the reflective surface of said mirror 14 casu quo positioned horizontally on the upper surface of said first window w₁, preferably between multiple shorter hairlines 38, positioned in sundial manner on the upper surface of said first window w₁, casu quo on the reflective surface of said mirror 14 at the locus of said hinge line 15 as shown in FIGS. 9B, 18D, 18E, 19B, 22, 23A and 23B. Said shadow-casting cords 19 serve simultaneously as support cords for shadow-casting rods casu quo shadow-casting beads 35 serving as bendable mirror positioning aids casu quo solar altitude tracking aids through shadow-casting communication with said hair line 37 on said first window w₁, casu quo with the upper light collecting surface of said PV cell module 21 casu quo of said first window w₁.

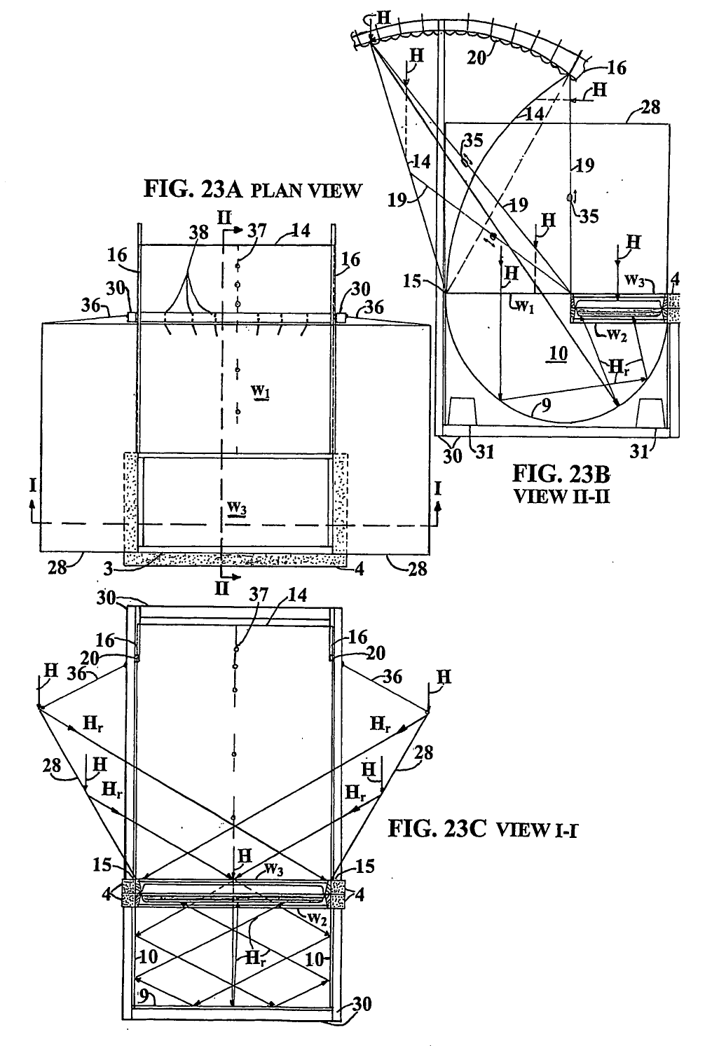

Optional novel components are introduced in the form of flat tiltable booster mirrors/reflectors 28, positioned with hinges near outer edges of said first and second windows perpendicular to said axis of rotation of said half-barrel shaped concave reflective cavity as shown in FIGS. 23A, 23B and 23C. Said booster mirrors serve to acquire and direct additional sunlight onto said PV cell modules and/or onto and through said first and third windows especially so in sunbelt latitudes and/or whenever said apparatus is left off-azimuth, thereby relaxing azimuth-tracking requirements.

As yet other useful components in the present invention are provided a second and a third sheet 7 of a material transparent to sunlight. Said transparent sheets 7 are installed window-like, in approximately horizontal position above said heat conducting second metal plate 1 casu quo above said second selectively surfaced absorber 1 at a distance of 10 (ten) to 20 (twenty) millimeters of said second metal plate 1, and of each other, thereby forming two insulating air chambers above said second metal plate casu quo indented tray casu quo absorber 1. Preferred transparent materials are low-iron glass having an anti-reflective coating for the upper, outermost casu quo third sheet and a highly transparent thin Fluoropolymer, for example Teflon FEP® for the intermediate sheet casu quo the second transparent sheet.

As yet other useful components in the present invention are provided sheets 13 of a material transparent to sunlight. Said transparent sheets 13 are installed in approximately horizontal position under said cooker cavity and sideways from said outer wall of said cooker cavity, closing off the windows casu quo apertures w₁ and w₂ above said concave reflective cavity 9, thereby creating a closed-off, still-air, concave reflective cavity 9, protected from incursion of for example rain, wind, dust, debris, spilled foods and the like. Preferred transparent materials are low-iron glass, having an anti-reflective coating on the surfaces facing the light and/or highly transparent polymers such as, for example, fluoropolymers, acrylics, polyesters, polycarbonates.

### Materials Useful in the Method and Apparatus of the Present Invention

First 1 and second 1 heat conducting metal plates are used as lower and upper high temperature light absorbers in food cooking environments. Preferred economical long life materials resistant to corrosion in said environments are ferritic stainless steels, sheet metal, for example types 409, 430 or 434, in the bright annealed surface quality. Said preferred material can have a 0.2% yield strength of 205 MPA at a stagnation temperature of 300 centigrade, said yield strength being higher than the yield strength of conventional more expensive 18% chrome, 8% nickel austenitic stainless steels, such as type 304. Further advantages of said preferred material are a low thermal expansion coefficient of less than sixty percent of said conventional stainless steel and last but not least an excellent heat conductivity of 24 watts per meter centigrade in the temperature range of twenty to two hundred centigrade; that means more than fifty percent better heat conductivity than said conventional austenitic stainless steel. Preferred sheet metal thickness ranges from about one tenth of a millimeter for small portable light duty cookers to about two millimeter for heavy duty professional cookers. Said sheet metal can be easily formed, even in said spectrally selective coated state into said cavity shaped first and second trays by well-known simple deep drawing techniques without intermediate reheating. Said ferritic stainless steel sheet metal is eminently resistant to stress corrosion and more importantly, to pitting types of corrosion caused by halogen ions such as chlorides as may be present in many waters and salted foods. For a 500 watts peak power cooker, convenient for a six person family, a total quantity of about one square meter of said ferritic steel material is required.

A preferred economical long life spectrally selective coating to be deposited on said ferritic stainless steel sheet metal is black chromium oxide in the benign trivalent state. Said black chromium oxide coating on ferritic stainless steel has been tested for high temperature stability up to four hundred centigrade and has shown no signs of degradation. Coatings absorptivity to coatings emissivity ratios (α/ε) of over 90/10 can be reached for long-life coatings on bright annealed ferritic stainless steel surfaces. Said coatings can be deposited by a continuous coil coating operation, alternatively on sheets, by a batch process.

Non-stick fluorocarbon (Teflon) coatings can be advantageously applied on one side (the side in contact with the food) of said coated ferritic stainless steel sheets.

For said shadow-casting cords 19 a suitable material is a stretchable casu quo elastic rubber, opaque casu quo black and provided with UV protection additives against aging casu quo provided with a textile, spun around said rubber cord for protection.

For the lower, first transparent sheet 7 a preferred material is 3 to 5 (three to five) millimeter thick low iron glass, advantageously equipped with a low reflection surface on the sunny side. A more preferred material, especially for mobile, transportable cookers is a light weight, highly transparent fluoropolymer, for example tradenamed Teflon FEP” 100A/200A or Hostaflon® thin film of 0.025 to 0.05 millimeter thickness, as this material is characterized by the highest available light transmissivity (in the order of 96 percent) combined with the lowest available refractive index of 1.34 and the highest critical angle of light incidence. The resistance of said fluoropolymer to photo-degradation is excellent, even at the high temperatures in the 200 centigrade range that may occur during stagnation conditions. In combination with said selective surfaces 1, its overall solar energy collection performance is better than glass and its low refractive index combined with its high critical angle of light incidence allows for more solar energy collection, thereby extending the operating window for solar cooking early in the morning and late in the afternoon, as well as in winter, spring and autumn seasons and on cloudy or hazy days when the diffused or scattered light component is large. Said fluoropolymer sheet is further characterized by excellent non-stick qualities, facilitating easy cleaning, should any food spill on and stain said normally transparent fluoropolymer sheet.

For the same reasons, for said upper transparent sheets 7, 8, a combination of a 3-5 (three to five) millimeter thick outer sheet of said glass and a 0.025 to 0.05 millimeter thick intermediate sheet of said fluoropolymer is recommended.

For mobile, lighter duty cooking operations two lighter, unbreakable polymer sheets are preferred as transparent windows above said second absorber 1, for example two of said fluoropolymer sheets 7, or a combination of a fluoropolymer intermediate sheet and a Tedlar®, acrylic, polyester or polycarbonate outermost sheet, communicating with and cooled by the ambient.

For said transparent sheets 13 suitable transparent materials are said glass, for stationary versions of said apparatus of the present invention. Transparent polymers such as, for example, fluoropolymers, acrylics, polyesters, and polycarbonates in the form of plates or films are preferred transparent materials for light-duty casu quo mobile applications. Materials with a transmissivity of 92% are readily available, materials with a transmissivity of 97% are available. For said 500 watts peak power cooker a total quantity of about 1.5 square meters of transparent sheet casu quo foil material is required.

For said half barrel shaped concave reflective cavity casu quo reflector 9 a variety of highly reflective materials may be used, depending on the cooking operation. Said materials may be in the form of curved glass mirrors or coated aluminum reflectors, for said stationary, heavy duty cooking operations. For mobile casu quo lighter duty cooking operations said highly reflective materials may be rigid, or low cost semi-rigid, such as for example aluminized cardboard. For many cooking operations said highly reflective materials may be flexible, fabricated for example from aluminized polyester films, aluminized foams. Materials with a reflectivity of 90% are readily available, materials with a reflectivity of 94% are available.

For said vertical upper 14 and lower flat reflectors 10 and the reflective sides 5, 6 of said hot box, similar considerations and resulting materials apply as for said concave reflective cavity.

For said 500 watts peak power cooker a total quantity of about 3 square meters of reflective casu quo mirror surface material is required out of which bendable mirror material is about one square meter.

For a PV cell module attaining 500 watts net to cell sunlight irradiation about one square meter of bendable mirror is required.

For a quality of life supply of PV electricity, enabling a six person family to enjoy electric light, a refrigerator and a television set casu quo a computer, about one third of a square meter of PV module will be required.

For non-metal support walls 3 of the cooking box, wood or plywood of a water and heat resistant type is a suitable material.

For electricity generation state-of-the-art PV cell panels casu quo modules can be positioned in approximately horizontal position under said bendable mirror 14.

### BEST MODES FOR CARRYING OUT THE PRESENT INVENTION

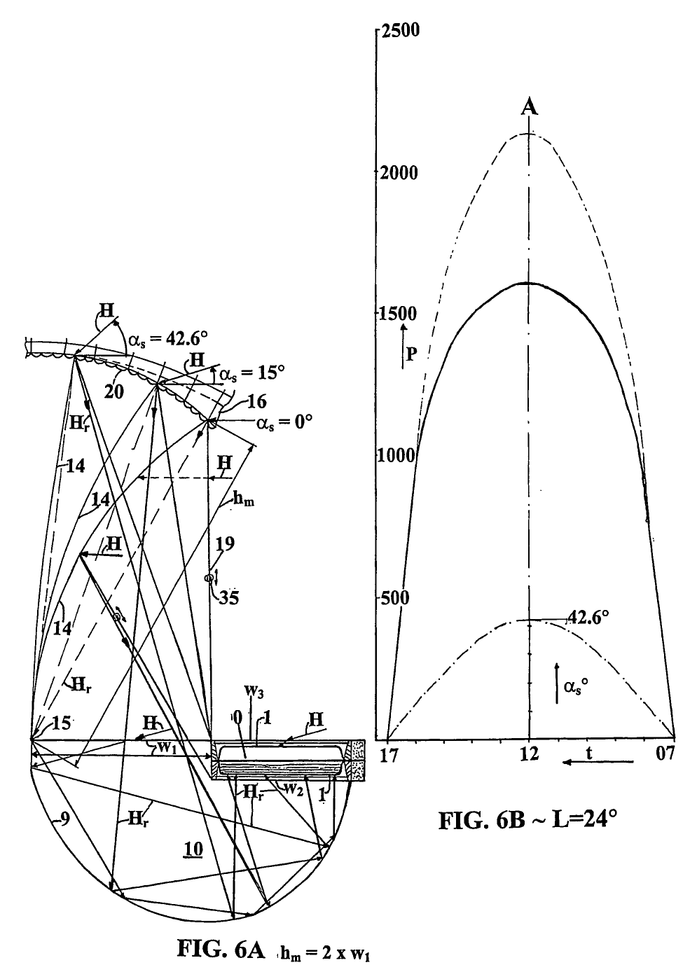

Referring now to FIG. 5A, a preferred embodiment of the apparatus is shown. The basic features of said preferred embodiment are similar to said basic apparatus, however, the height of said bendable mirror 14 is increased, thereby enabling said bendable mirror to acquire more additional sunlight and—advantageously using its tiltable and bendable advantages—reflectively direct with favorable angles of incidence, said more additional sunlight onto said PV cell module casu quo onto and through said first window w₁ and onwards via said half-barrel shaped concave reflective cavity 9 to the underside of said heat conducting tray 1 above said second window w₂, thereby further augmenting net to food cooking power.

Surprisingly I have found that increasing the height of a tiltable and bendable mirror is much more rewarding in terms of augmented net to PV module irradiation casu quo net to food cooking power than increasing the height of a fixed flat casu quo a tiltable only flat mirror, this even more so when the sun is low, such as is the case in winters, at high latitudes, and worldwide in early mornings and late afternoons. As the height of said tiltable and bendable mirror is increased, the optimum mirror tilt angles track is modified, said track starting in the morning casu quo ending in the evening at a lower tilt angle and more curved shape, said track reversing at noon at a lower tilt angle. The apparatus of said preferred embodiment is capable of providing further augmented net to food cooking power, for example, at 24°N, December 21, winter solstice, simulated net to food cooking power for said preferred embodiment with 50% higher mirror is shown in FIG. 5B. Peak warm-up power is increased to about 2,100 watts/m² cooker box light aperture, availability of more than 250 watts net sustainable bottom power for a 50×50 cm cooker cavity is increased to about 8 hours, from 08.00 hours to 16.00 hours.

Bringing half a liter of 15° C. water to boiling temperature of 100° C. in a kettle on a one kilowatt natural gas fired gas range burner takes about six minutes casu quo one hundred watt hours of gas to transfer a net amount of heat of fifty watt hours to the water, thermal efficiency being about fifty percent. For convenient fast warm-up and cooking times a hot box s type light cooker according to the present invention, adequate for a six person family, consisting of two adults and four children, should be sized for a net to food peak power of about 500 watts.

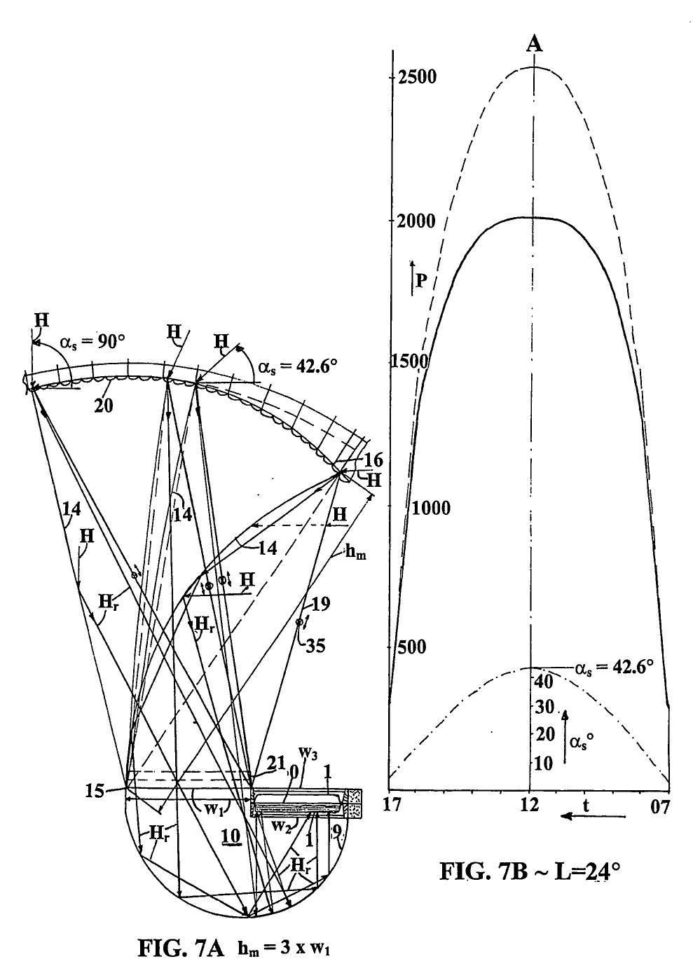

Referring now to FIG. 6A, a further preferred embodiment of the apparatus useful in the method is shown. The basic features of said further preferred embodiment are similar to said basic apparatus, however the width of said first window w₁ is increased casu quo widened, thereby widening the light-acquiring aperture between said cooker cavity and the hinged edge of said bendable mirror, and increasing the width perpendicular to said axis of rotation of said half-barrel shaped concave reflective cavity. Furthermore the height of said bendable mirror is increased to double the widened width of said first window w₁, thereby enabling said widened first window w₁ and said higher bendable mirror to acquire still more additional sunlight with favorable angles of incidence onto said PV cell module casu quo onto and through said first window w₁ and onwards via said widened half-barrel shaped concave reflective cavity 9 to the underside of said heat conducting tray above said second window w₂, thereby providing still further augmented net to food cooking power. For example, at 24°N, December 21, winter solstice, at the same insolation as in the base case, an apparatus having a 30% wider first window w₁ combined with a 30% higher tiltable and bendable mirror enables an increase in net to food peak warm-up power to about 2,100 watts/m².

Simulated net to food cooking power for said further preferred embodiment is shown in FIG. 6B. In this further preferred embodiment an apparatus having a 50 cm by 50 cm cooker cavity, a 50 cm by 65 cm first window and a 50 cm wide by 1.30 m high tiltable and bendable first booster mirror in operation at 24N, December 21, winter solstice, can provide a peak warm-up power of about 525 watts and a sustainable bottom power availability of more than 250 watts for about 8 hours (08.00-16.00), casu quo of more than 350 watts for about 5 hours (09.30-14.30).

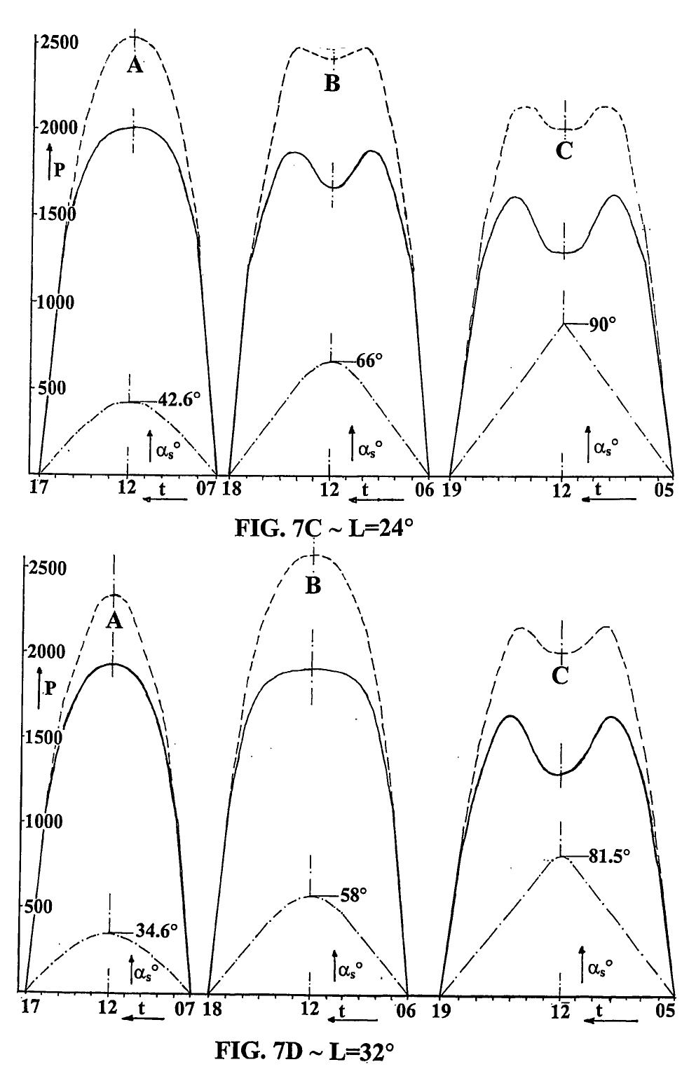

Referring now to FIG. 7A a still more preferred embodiment of the apparatus useful in the method is shown. The basic features of said still more preferred embodiment are similar to said basic apparatus, however, the width of said first window w₁ is 30% wider than the width of said second and third windows w₂ and w₃ and the height of said hinged, tiltable and bendable mirror is further increased to three times the width of said window w₁, thereby enabling said widened first window w₁ and said heightened bendable mirror 14 to acquire still more sunlight with favorable angles of incidence onto said PV cell module 21 casu quo onto and through said widened first window w₁ and onwards via said widened half-barrel shaped concave reflective cavity 9 to the underside of said heat conducting tray 1 above said second window w₂, thereby providing still more augmented net to food cooking power. For example at 24°N, December 21 winter solstice, for said apparatus having a 30% wider first window w₁, and having bendable mirror height of three times the width of said window w₁, simulated net to food cooking power is shown in FIG. 7B. With said still more preferred embodiment peak warm-up power can be increased to about 2,500 watts/m² cooker box aperture. In said still more preferred embodiment, for example, an apparatus having a 35 cm×70 cm cooker cavity, a 45 cm×70 cm first window combined with a 70 cm wide×1.35 m high bendable mirror can provide at 24°N, December 21, winter solstice, a peak warm-up power of about 600 watts and a sustainable bottom power availability of more than 300 watts for about 8 hours (08.00-16.00) casu quo of more than 400 watts for about 6 hours (09.00-15.00). For said still more preferred embodiment according to FIG. 7A simulated net to food cooking power in watts/m² cooker cavity light aperture area as a function of solar altitude angle αₛ during the day on winter solstices, spring and autumn equinoxes and summer solstices is shown:

In FIG. 7C at 24° parallels

In FIG. 7D at 32° parallels

In FIG. 7E at 40° parallels

In FIG. 7F at 48° parallels

In FIG. 7G at 56° parallels

In FIG. 7H at 64° parallels

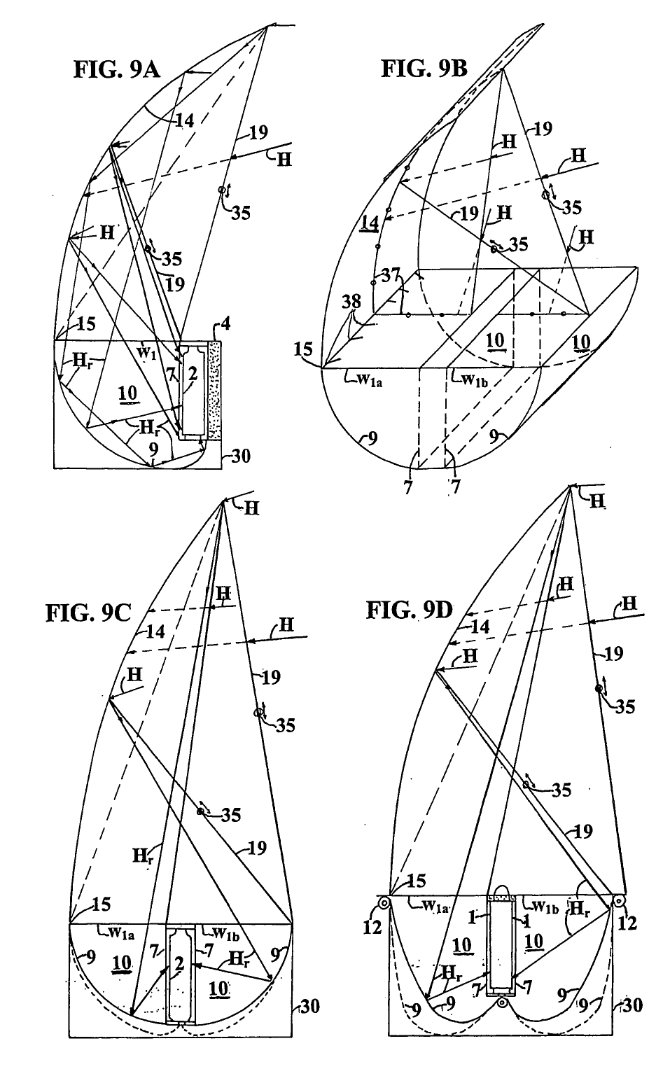

Net to food cooking power, attainable worldwide at said different latitudes and in said different seasons based on glass transmissivity of 92% and mirror reflectivity of 90% is shown simulated in FIG. 11. Net to food cooking power attainable as shown can be increased by about 10% through the use of presently less readily available glass material having about 97% transmissivity and mirror material having about 94% reflectivity.

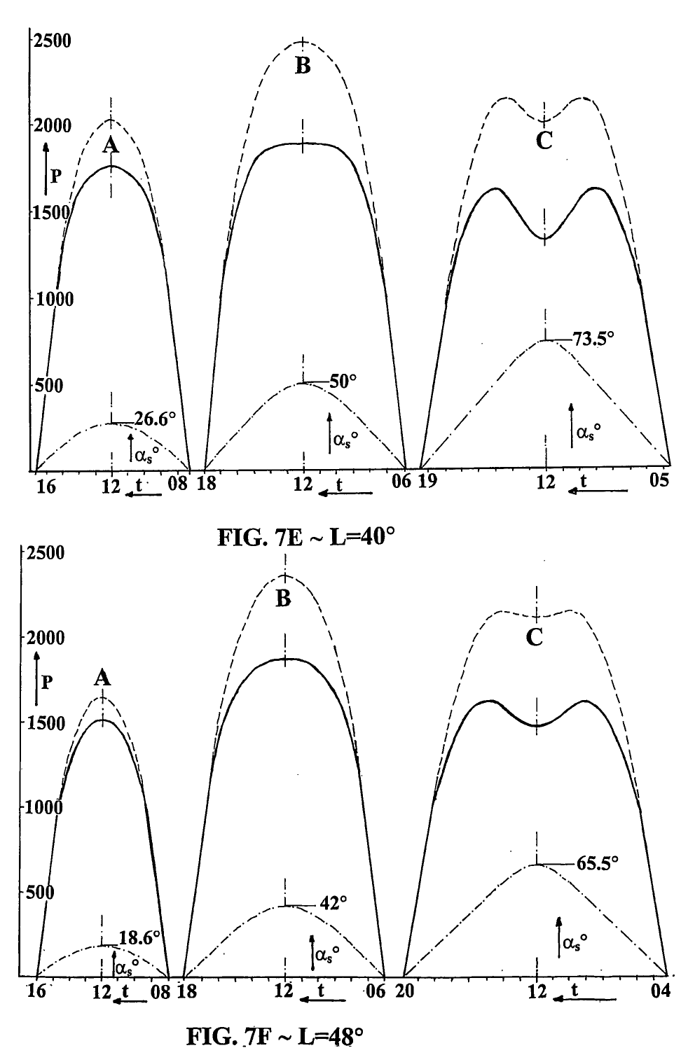

Referring now to FIG. 8A a reduced cost embodiment of the apparatus useful in the method is shown, suitable for cooking on light in equatorial casu quo tropical regions and/or under very windy circumstances precluding the use of high mirrors. The basic features of said reduced cost embodiment are similar to said basic apparatus of FIG. 2A, however, the width of said window w₁ is increased, the upper mirror is flat and its height is reduced to about equal to the width of said first window w₁ and said cover cavity 0 with its tray 1 are replaced by an insulating board. Simulated net to food cooking power of said reduced cost embodiment of the apparatus useful in the method on December 21, the winter solstice at 24°N, is shown in FIGS. 8B/8C, peak power is about 1,100 watts/m² (at the equator about 1,200 watts/n²) and a target sustainable power of 1,000 watts/m² to said cooker cavity bottom can be made available for about 4 hours per day (at the equator about 6 hours per day). Simulated net to food cooking power at spring and autumn equinoxes and summer solstice at 24°N is shown in FIGS. 8D and 8E.

Referring now to FIG. 9, another preferred embodiment of the apparatus useful in the method is shown. In this other embodiment a set of two PV cell modules casu quo a light-transparent cavity is installed, permanently or temporarily, casu quo removable in approximately vertical and central position in said half-barrel shaped concave reflective cavity, now having two light acquiring apertures casu quo first windows, w₁a and w₁b, sideways of said light transparent cavity. Said light transparent cavity being capable of receiving casu quo accommodating a movable cooker casu quo heater cavity suitable for heating liquids and/or of receiving casu quo accommodating commercially available 1.5 liter PET water bottles, which are convenient for purification of drinking water by a combination of light and heat. Said light transparent cavity may be made of said low-iron glass having an anti-reflective surface, the surface when in use facing incoming light, alternatively made of a highly transparent polymer. Said movable cooker casu quo heater cavity may be made of said highly heat conducting material, having outer surfaces, the surfaces when in use facing incoming light, coated with said spectrally selective coating. Said movable cooker casu quo heater cavity being maintained in said transparent cavity with a distance of 10 (ten) to 20 (twenty) millimeters between the outer walls of said cooker casu quo heater cavity and the inner walls of said light transparent cavity, thereby creating an insulating air chamber reducing heat losses. The central, lower part of said half-barrel shaped concave reflective cavity is advantageously lifted up, for example by means of a bar or a roller bar, thereby converting said half-barrel shape into two approximately quarter-barrel shapes both having variable curvature optimized for augmented net to liquid cooking power casu quo augmenting net to drinking water light and heating power.

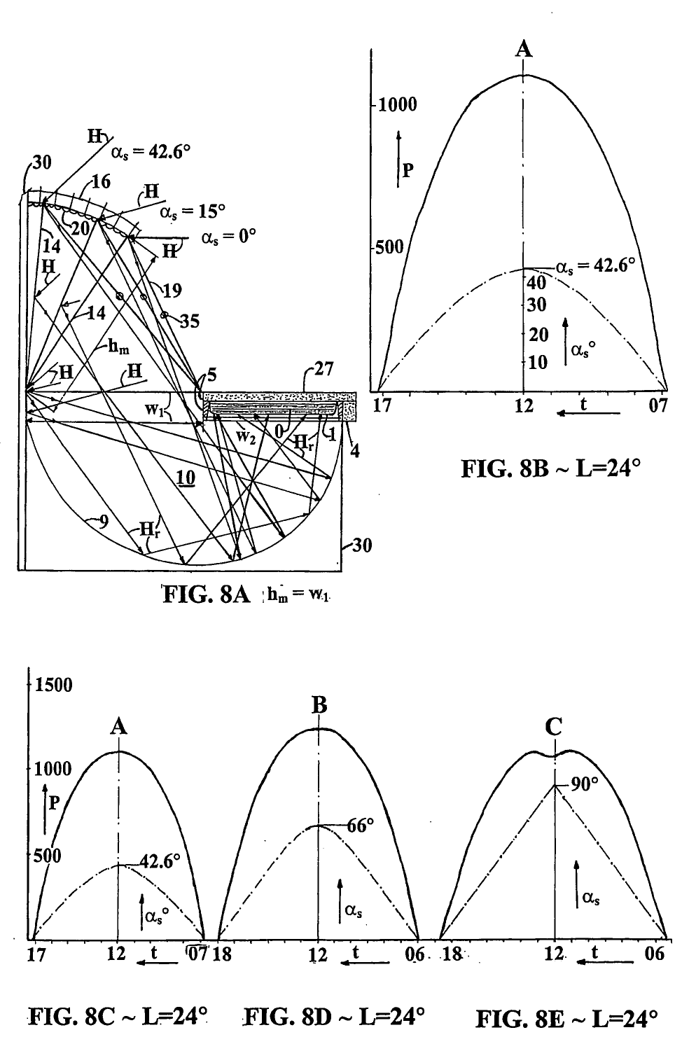

Referring now to FIG. 10A, 19 and 22 for cooking and for electricity generation, preferred embodiments of the apparatus useful in the method are shown. In these embodiments PV panels casu quo modules, hereinafter called PV module 21, are positioned in approximately horizontal position on ridges 22 perpendicular to said mirror 14 under casu quo sideways from said hinged tiltable and bendable mirror casu quo reflector 14, acting simultaneously as a chimney providing draft for a warmed air stream warmed-up upon cooling the underside of said PV cell module.

The height of said mirror 14 can be variable, for example from one to many times the width of said PV module. A practical mirror 14 height is about three times the width of said PV module as measured perpendicular to the hinge line of said mirror 14. For said preferred embodiments having said practical ratio 3 of mirror 14 height hₘ to PV module width w₁ simulated net to PV cell sunlight irradiation as a function of solar altitude angle αₛ during the day is shown in FIG. 10B. At 40°N, December 21, the winter solstice, net to cell peak net irradiation is about 1,600 watts/m² of PV module area even at a low as of only 26.6°, where a state-of-the-art non-tracking PV module is shown to reach about 250 watts/m² peak net to cell irradiation. At 08.00 am. and 16.00 p.m., when αₛ is about 6°, a state-of-the-art non-tracking PV module receives no net to cell sunlight irradiation, whereas a PV cell module incorporated into the apparatus useful in the method receives a practical and convenient net to cell sunlight irradiation of about 500 watts/m². At 40° and higher latitudes in spring and summer practical levels of PV power can be generated and used to charge batteries in the early hours of a day before there is a demand for cooking power. An additional advantage of said preferred embodiment is that at lower solar altitude angles αₛ, ambient temperatures are generally lower. PV cell performance casu quo efficiency of conversion of sunlight to electricity is augmented by about 0.4 percent for every degree centigrade drop in temperature. For said preferred embodiment for electricity generation according to FIG. 10A simulated net to cell sunlight irradiation in watts/m² as a function of solar altitude angle αₛ during the day on winter solstices, spring and autumn equinoxes and summer solstices is shown:

In FIG. 10C at 24° parallels

In FIG. 10D at 32° parallels

In FIG. 10E at 40° parallels

In FIG. 10F at 48° parallels

In FIG. 10G at 56° parallels

In FIG. 10H at 64° parallels

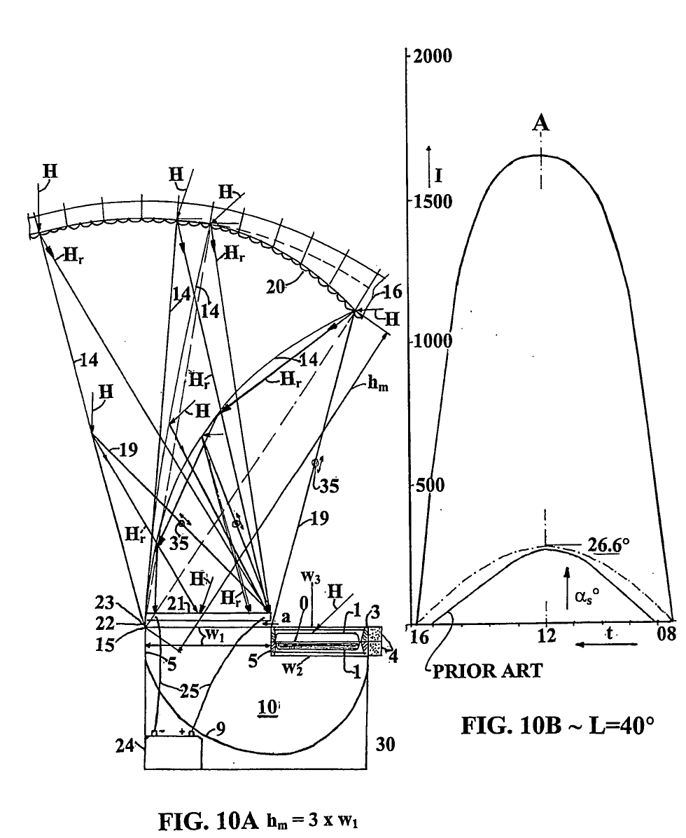

PV power cell net light irradiation attainable worldwide at said different latitudes and in said different seasons is shown simulated in FIG. 12, based on cover glass transmissivity of 92% and mirror reflectivity of 90%. Net light irradiation attainable as shown can be increased by about 10% through the use of presently less readily available materials, such as glass having about 97% transmissivity and mirror material having about 94% reflectivity.

### INDUSTRIAL APPLICABILITY

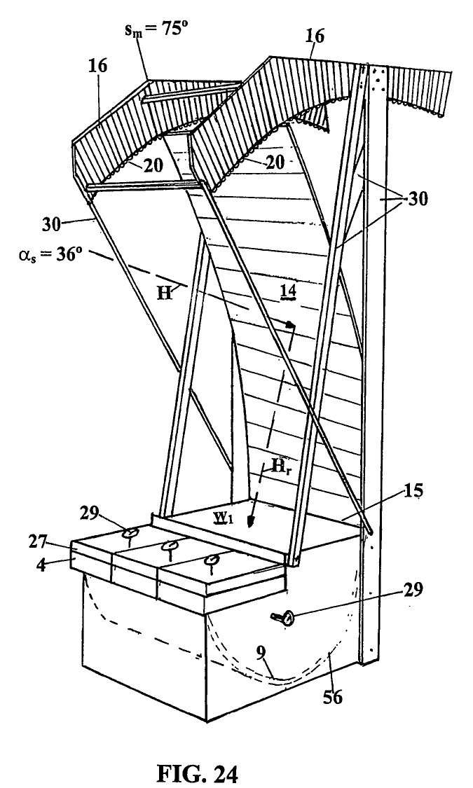

Several embodiments were tested by the inventor in the Almeria area in Southern Spain in November 2003 for various cooking operations, for example in FIG. 24, a preferred embodiment suitable for windy environments is shown, incorporating two upper guide rails 16 supported by a stabilized upper structure 30 with tie-rods 30 for maintaining optimum mirror guide rail profile 20 position in relation to said mirror hinge line 15 and fine (one degree) tuning of mirror tilt angle, said preferred embodiment as shown in FIG. 24, having three cooking trays with top insulation, bendable mirror surface area 1.35 m×0.625 m, first window area 0.45 m×0.625 m, trays area three times 0.35 m×0.20 m. was tested for cooking foods such as: cooking of brunch consisting of fried eggs, fried bacon and fried tomatoes. In tray 1: fried eggs for three persons, in tray 2: fried bacon for three persons, in tray 3: fried tomatoes for three persons. Said food items were fried in 20 grams each of olive oil in less than 15 minutes at 144° C. oil in tray temperature. Said cooked food items had the following characteristics:

Fried eggs, sunny side up, well done. Fried bacon: crisp, well done. Fried tomatoes: juicy, tender, well done. All said fried food items had excellent taste and texture.

For said test the following geographical climatic and insolation data are of relevance:

Date of test: Nov. 12, 2003.

Location of test: Almeria area, Southern Spain. Latitude: ˜37°N, longitude: ˜2°W.

Sunrise at 07.00 hrs; sunset at 17.00 hrs (universal times)

Time of test: 13.00-13.15 hrs (local time=universal time+1 hour).

Ambient temperature: 18° C., Wind speed: 4-5 Beaufort, Sky: hazy.

Solar radiation on horizontal ground: 535 watts/m², beam radiation: 920 watts/m.

Solar radiation measured with calibrated Kipp pyranometer.

Solar altitude angles: ˜36°, Solar azimuth angles: ˜2°-6°.

Mirror tilt angles: 75°,

13.00 hrs: Olive oil in tray temperature: 144° C. Top insulation slabs lifted off, eggs, bacon slices and tomato segments positioned in trays.

13.03 hrs: Top insulation slabs positioned on trays.

13.15 hrs: Eggs, bacon slices and tomato segments ready to be eaten.

Temperature measurements: in tray temperatures were measured with K-type (chromel-alumel) thermocouples and bimetal thermometers, temperatures inside the half-barrel shaped concave reflective cavity were measured with bimetal thermometers, a temperature of 71° C. was measured between 13.00 and 13.15 hours.

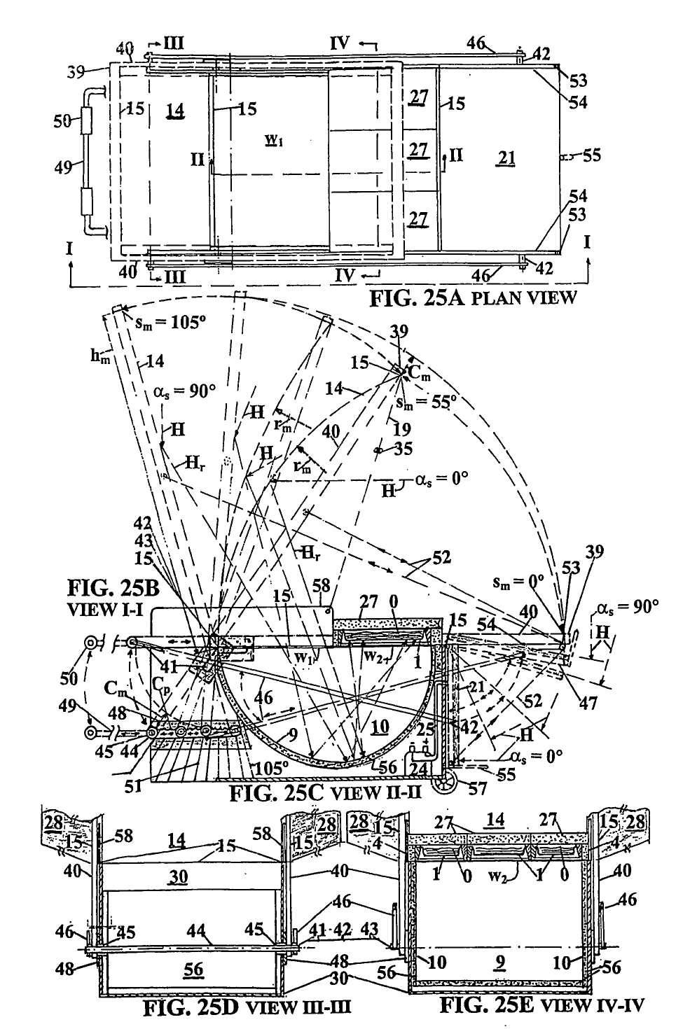

For example in FIGS. 25A-25E, views are shown of a most preferred compact embodiment without upper structure, optimized for simultaneous convenient cooking and/or convenient electricity generation on sunlight. In this embodiment a tiltable and bendable mirror/reflector 14 is suspended by means of two long hinges, hereinafter called upper and lower hinges. By means of the upper hinge 15 said mirror is attached in a rocking manner to a cross bar 39 rigidly connecting the ends, hereinafter called the upper ends of two pivoted sliding levers casu quo two sliding rocking arms, hereinafter called rocker arms 40. By means of the lower hinge 15 said mirror is attached in a rocking manner to the frame of the cooker at the locus line of the outer edge of said first window w₁. Each of said rocker arms is equipped with a slot 41 plate casu quo a slot having a width adequate for snugly accommodating a pivot 42 casu quo a roll 43 on said pivot and having a slot length at least equal to the maximum desired mirror compression Cₘ as shown in FIG. 17C casu quo 17D as a function of hₘ. The other ends of said rocker arms, hereinafter called the lower ends, are preferably connected to each other by a shaft 44 casu quo a hollow shaft equipped with rolls 45 adequate for snugly following rocker arm pulling guide rail profiles casu quo mirror compression guide rail profiles, hereinafter called guide rail profiles Cₚ. The ends of said shaft are preferably equipped with extensions casu quo extensions with rolls functioning as pivots 42 casu quo pivots with rolls 43 adequate for snugly accommodating slots 41 casu quo slits in casu quo on connecting rods 46 installed on both sides of said cooker frame and connecting said shaft extensions to pivots 42 positioned on a hinge 15 supported rocking rack 47 carrying a PV cell module 21 casu quo PV cell modules. In operation, said rolls 45 and said shaft 44 are forced to travel under said guide rail profiles which are preferably incorporated in wear resistant guide rail plates 48 equipped with punched-in serial numbers casu quo registration numbers casu quo National and/or State license plate numbers qualifying for emission credits and installed in a stable, rigid manner below and perpendicular to said hinge lines 15 of said mirror 14 on each side of the frame of said cooker. For ease of said forcing a handle bar 49 with grips 50 can be attached, preferably in a rocking manner to said shaft 44, as shown in FIGS. 25A and 25B. Said guide rail plates are characterized by possessing a profile that results in said mirror compression Cₘ, as shown in FIG. 17C casu quo 17D as a function of hₘ, yielding an optimum mirror curvature rₘ in combination with a corresponding mirror tilt angle sₘ for a particular mirror height hₘ approximately according to the relationship:

$${r}_{m} = \frac{{h}_{m} - {C}_{m}}{2 sine ( {90}^{∘} - {s}_{m}^{∘} )}$$

On each side of the cooker frame, a series of lines at desired degree intervals pointing at said lower hinge 15 line are installed on casu quo under said guide rail plates 48 like sundial type dials, hereinafter called dials 51. Said dials show the tilt angle of said rocker arms 40 casu quo the tilt angle of said mirror 14. In operation said dials enable easy and accurate positioning of said rocker arms, thereby enabling optimum mirror tilt angles in combination with optimum mirror curvatures for optimum sunlight harvesting and onward reflective transport of harvested sunlight by said mirror 14, simultaneously easy and accurate azimuth tracking is enabled, a person conveniently standing in the shade behind said mirror 14 can, in one movement, aim the whole apparatus including mirror 14 and PV cell module 21 at the sun by simply putting casu quo keeping said rocker arm 40 casu quo the vertical edge of said mirror 14 and elastic cord 19 in a vertical plane parallel to the rays of the sun.

In operation, as said shaft 44 with said rolls 45 are forced to travel back and forth casu quo down and up and down under said guide rail profile, connecting rods 46 attached to said shaft 44 are forced to push casu quo pull a hinge 15 supported rocking rack 47 holding a PV cell module 21 casu quo PV cell modules into positions optimized for acquiring sunlight onto said PV cell modules at optimum angle of incidence, thereby enabling highly efficient electricity generation in a low cost two-axis sun tracking manner that can be optimized for all latitudes and/or seasons. Optional rocking flat booster mirrors 28 having a height up to about equal to the height of said bendable mirror 14 and having a width up to about half the width of said bendable mirror 14 are attached with hinges 15 to said rocker arms 40 on both sides of said bendable mirror 14. Said booster mirrors serve in open position with an optimum opened angle of about 120 degrees to further increase the acquisition of sunlight or serve—at the option of the cook—as blinds, in closed position blocking the glare of said bendable mirror 14 whenever the cook needs to work on casu quo in said cooking trays.

To accommodate variations of solar altitude angles αₛ at different latitudes and/or in different seasons the points of engagement of said connecting rods 46 on said PV cell support rack casu quo the location of the pivots 42 on said support rack can be optimized, thereby enabling at all latitudes and in any season favorable angles of incidence of sunlight on said PV cells. For example in FIG. 25B the outer curve indicating the PV cell modules tilt angles corresponds to operations between the tropics, e.g. between 0° and 24° latitude where αₛ may reach about 90°. For PV cell cooling draft purposes a minimum PV cell module slope angle of 10° is maintained at all latitudes and all seasons. More inward curves correspond for example to operations in tropical winters. Similarly the inner curve shown corresponds to operations at about 40° latitude where in summer αₛ reaches about 74° at the most.

As an alternate embodiment to said connecting rods compelling the rocking movement of said PV cell module support rack, pulling ropes casu quo cords 52 are installed between suitable points of engagement on said rocker arms 40 and said PV cell support rack, for example via pulleys 53 installed on casu quo in supports 54 extending from the frame of said cooker. Optimization of PV cell tilt angle for latitudes and/or seasons can be accomplished by optimizing the points of engagement of said ropes casu quo said cords on said rocker arms and/or said PV cell support rack. For ease of optimizing tilt angle of said PV cell support rack, a shadow-casting gnomon 55 is positioned on the outer edge of said PV cell support rack, as shown in FIG. 25B, and whereby a small or no shadow is indicative of an optimum position.

In this embodiment the curved and flat reflective surfaces casu quo walls of said half-barrel shaped concave reflective cavity are insulated on their convex side casu quo their outside surfaces. In operation, said insulated 56 reflective walls under said cooking trays enable an increase in temperature inside said half-barrel shaped concave reflective cavity, by putting to good use any heat resulting from non-ideal reflections inside said concave reflective cavity. As a result the hot surfaces on the underside of said cooking trays “face” a “space” and a reflecting surface which is hot and has a low absorptivity, consequently heat losses from said cooking trays are reduced, net to food cooking power is increased and higher food processing temperatures can be reached faster and maintained longer.

To further reduce heat losses from said concave reflective cavity through said first window w₁ reflective hinged wind shields 58 are installed, perpendicular to said lower hinge 15 line of said mirror 14 on both sides of said first window w₁. In operation said windshields 58 can be held upright by shadow-casting elastic cords 19 with shadow-casting beads 35 installed between said windshields and said cross bar 39.

This most preferred compact embodiment provides a practical personal clean energy system, other embodiments of the present invention enable many enhanced natural sunlight operations such as for example accelerating the growth of plant seedlings or sunning the human body by taking a sunbath under said tiltable and bendable mirror 14.

The present invention has been described in an illustrative manner. In this regard it is evident that those skilled in the art or science casu quo the commerce to which the present invention pertains, once given the benefit of this disclosure, may now make modifications to the method and the specific embodiments described herein without departing from the spirit of the present invention. Such modifications are to be considered within the scope of the present invention which is limited solely by the scope and spirit of the appended claims.

1. A method for a achieving worldwide reduction of carbon dioxide emissions and/or worldwide reduction of deforestation characterized by providing for many people the steps for and/or the opportunity for earning and/or accruing rights and/or credits selected from the group consisting of greenhouse gases emission rights, carbon dioxide equivalents emission rights, carbon dioxide emission rights, tradable greenhouse gases emission avoidance credits, tradable carbon dioxide equivalents emission avoidance credits, tradable carbon dioxide emission avoidance credits and certified emission reductions the value of which rights and/or the value of which credits and/or certified emission reductions can be monetized for paying wholly or partly for the cost of said method and for the cost of an apparatus qualified for and/or licensed for said accruing of said rights and/or for said accruing of said credits and/or for alternatively and/or additionally creating a source of ongoing revenue for users of said method and apparatus and/or for governments and/or organizations that promote the introduction and ongoing use of the method and apparatus of the present invention, said method being further characterized in operation by a synergic combination of augmented net to food cooking power on sunlight with augmented net electricity generating power on sunlight, thereby augmenting convenience of cooking and/or electricity generation on sunlight to such a high level that many people are induced to substitute carbon containing fuels for lighting and/or cooking by sunlight and in doing so said people are avoiding exposure to harmful emissions causing widespread lung and eye diseases and/or said people are rewarded by affordable access to electricity, entertainment, education and improved health, said method furthermore being characterized in operation by the steps for greatly accelerating and greatly augmenting net to food cooking power and/or net electric power from sunlight at all solar altitude angles, especially so at low solar altitude angles, resulting in better quality meals through shorter cooking times and/or resulting in shorter battery charging times, conveniently resulting in reduced sun tracking labor, more frequent and more varied usefulness during prolonged periods of usefulness and more widespread usefulness over wider latitudes, the foregoing favorable characteristics resulting from compounding power augmentation contributions by a sequence of individual inventive net to food cooking power augmentation steps and/or net electric power augmentation steps, said method comprising any or all of the following steps:
(a) acquiring sunlight onto PV cells, assembled into modules, hereinafter called PV cell modules and/or through approximately horizontal transparent surfaces, hereinafter called first window or first windows and second window or second windows, positioned approximately side by side above a concave reflective cavity or a plurality of reflective cavities of approximately half-barrel shape having its axis of rotation parallel to the meeting line of said first window with said second window and being capable of reflectively directing a major part or all of sunlight acquired by said first window to the underside of said second window, said second window transmitting said acquired sunlight onwards to a highly heat conducting underside of one or more well insulated cooker cavities, positioned above said second window, thereby providing augmented net to food cooking power to food, positioned on said highly heat conducting underside of said one or more well insulated cooker cavities;
(b) acquiring additional sunlight onto an adjustable tiltable and adjustable bendable reflector or mirror, positioned with lower hinge means near the outer, external edge of said first window, parallel to the axis of rotation of said half-barrel shaped concave reflective cavity, said mirror hereinafter called bendable mirror, said bendable mirror being capable of having variable tilt angle and variable curvature, enabling said bendable mirror to reflectively direct a major part or all of said additionally acquired sunlight onto one or more PV cell modules and/or through said first window with more favorable angles of light incidence for onward reflective transport of said sunlight to the underside of said second window for upward transmission of said sunlight through said second window to said heat conducting underside of said one or more well insulated cooker cavities, positioned above said second window, thereby providing further augmented and accelerated net to food cooking power to food, positioned on said highly heat conducting underside of said one or more well insulated cooker cavities, said step for acquiring additional sunlight also comprising the step for providing guide means for simple, accurate azimuth tracking and comprising also the step for providing one or more shadow-casting rods or beads communicating in shadow-casting manner with said bendable mirror and said PV cell module and/or said first window and comprising furthermore the step for providing one or more guide rails, each equipped with a mirror bending by mirror compression profile and mirror position marker means and/or mirror position holding means enabling positioning of said adjustably tiltable and adjustably bendable mirror in a simple, reproducible manner in optimum mirror tilt angle and optimum mirror curvature for optimum acquisition of additional sunlight at every solar altitude angle prevailing at a relevant time of the day, day of the year and latitude for optimum instantaneous reflective direction of a major part or all of said additionally acquired sunlight onto said PV cell modules and/or onto said first window with more favorable angles of incidence onto said PV cell modules thereby providing further augmented and accelerated PV cell power and/or onto said first window for onward transmission of said additionally acquired sunlight via said half barrel shaped concave reflective cavity and through said second window to said highly heat conducting underside of said one or more well insulated cooker cavities positioned above said second window, thereby providing still further augmented and accelerated net to food cooking power to food, positioned on said highly heat conducting underside of said one or more well insulated cooker cavities;
(c) acquiring further additional sunlight onto one or more PV cell modules positioned on a rocking rack supported in a hanging manner by hinge means attached parallel to said lower hinge means of said bendable mirror to an upper edge of said rocking rack and the edge of the structure of the apparatus furthest away, parallel to and at the level of said lower hinge means of said bendable mirror, said PV cell module hereinafter called rocking module being compelled by said additional sunlight acquiring movements of said bendable mirror and/or said structure of the apparatus to track the sun in a two-axis tracking manner for optimum acquisition of said further additional sunlight with favorable angles of incidence onto said one or more rocking modules at all times and latitudes;
(d) acquiring still further additional sunlight onto and through a third approximately horizontal transparent surface, hereinafter called third window or third windows, provided and positioned above one or more well insulated cover cavities provided with the same dimension as said one or more cooker cavities, said cover cavities being positioned in mirror-image or upside down arrangement above and on top of said one or more cooker cavities, said third window transmitting said acquired still further additional sunlight to a highly heat conducting topside, positioned under said third window of said cover cavity, furthermore providing the surface, illuminated when in operation of said highly heat conducting topside of said cover cavity with said spectrally selective coating possessing said high absorptivity for said acquired further additional sunlight and possessing low emissivity for radiation of infrared light or radiation of heat from said illuminated spectrally selective surface, said spectrally selective surface enabling instant conversion of a major part or all of the energy contained in said acquired still further additional sunlight to heat, heat being conducted instantly, with minimum resistance through said highly heat conducting topside of said cover cavity from where heat is radiated to foods, beverages or any materials positioned in the cavity under and below said highly heat conducting topside of said cover cavity, thereby providing still more augmented net to food cooking power to said foods, beverages or other materials;
(e) acquiring optimum quantities of sunlight onto said one or more PV cell modules, onto said tiltable and bendable mirror and onto and through all said windows by enabling in one movement easy and accurate aiming of the whole apparatus comprising said one or more PV cell modules, said mirror and all said windows at the sun by a person conveniently standing in the shade behind said tiltable and bendable mirror;
(f) converting instantly a major part or all of the energy contained in said acquired and additionally acquired sunlight reaching said one or more PV cell modules to electricity and/or converting said sunlight reaching said highly heat conducting underside of said cooker cavities to heat by means of a spectrally selective coating deposited on the surface illuminated when in operation, said spectrally selective coating possessing high absorptivity for said reflectivity transmitted sunlight, said coating possessing low emissivity for radiation of infrared light or radiation of heat from said illuminated spectrally selective surface, said spectrally selective surface enabling instant conversion of said light energy to heat, said heat being conducted instantly with minimum resistance through said highly heat conducting underside of said cooker cavities, thereby providing greatly augmented net to food cooking power to food, positioned in intimate heat conducting communication on said highly heat conducting underside of said one or more well insulated cooker cavities;
(g) storing said electricity generated by said one or more PV cell modules in one or more batteries, said one or more batteries preferably being positioned within the structure of said apparatus, said one or more batteries simultaneously serving as ballast, providing wind stability;
(h) acquiring optimum quantities of sunlight onto said selective surfaces by providing reflective surfaces on the inner walls of said support frames of said absorbers or trays, said reflective surfaces serving simultaneously as reflective insulation against heat losses from said trays to the ambient;
(i) reducing heat losses by providing insulation on the outer walls of said support frames of said absorbers or trays, said insulation possessing reflective surfaces;
(j) reducing heat losses by temporarily positioning insulating slabs over the tops of said trays or said cooker cavities apertures, said insulating slabs possessing reflective surfaces;
(k) reducing heat losses by providing insulation on the outside surfaces of said reflective walls of said half-barrel shaped concave reflective cavity;
(l) reducing heat losses by installing reflective wind shields perpendicular to said lower hinge means of said bendable mirror on both sides of and upwards from said first window, optionally for convenience also from said second window;
(m) reducing heat losses, simultaneously protecting spectrally selective surfaces by providing thin sheets of a highly transparent material, such as for example a fluorocarbon polymer such as Teflon FEP®, one of said thin sheets being installed at some distance under said highly heat conducting underside of said cooker cavity, thereby providing protection to said spectrally selective surface coated on said highly heat conducting underside simultaneously providing two insulating air chambers between said spectrally selective surface and said second window, thereby reducing heat losses and providing still more net to food cooking power, another of said thing sheets being installed at some distance above said highly heat conducting topside of said cover cavity, thereby providing protection to said spectrally selective surface coated on said highly heat conducting topside of said cover cavity and providing two insulating air chambers between said spectrally selective surface and said third window, thereby reducing heat losses and providing still more net to food cooking power;
(n) improving heat transfer to foods, beverages or any other materials, simultaneously reducing surface temperatures of light absorbing surfaces, conveniently reducing radiant and convective heat losses from said light absorbing surfaces by shaping said highly heat conducting underside of said cooker cavity, optionally also of said highly heat conducting topside of said cover cavity as concave trays, said concave trays together enclosing a cavity suitable for positioning food and/or beverages directly on the lower ones of said concave trays, for heating and/or cooking said foods and/or beverages, while in direct, intense, intimate heat conducting communication with said highly conducting underside or concave tray of said cooker cavity as heat source, said concave trays having been provided on their convex surfaces, the surfaces illuminated when in operation, with said spectrally selective coating, net to food heat transfer coefficients being improved compared to prior art cooking in vessels by an order of magnitude, thereby providing greatly augmented net to food cooking powers;
(o) enabling fast response to available solar radiation by providing improved angles of incidence for solar radiation onto said one or more PV cell modules and/or onto said windows and by reducing thermal inertia or cooking operations by cooking foods and/or heating beverages directly on and/or in one or more highly heat conducting thin-walled light-weight low-thermal inertia cooking trays having a spectrally selective coating on their convex outer surfaces, characterized in operation by instantly reacting positively to acquired sunlight, instantly converting said sunlight to heat, simultaneously delaying heat losses by temperature-dependent heat radiation, said one or more cooking trays, while in operation, furthermore being characterized by being in whole tray surface contact or intimate highly heat conducting communication with foods and/or beverages positioned directly on said one or more trays, resulting in augmented energy fluxes from acquired light to food, while simultaneously reducing temperatures of light-absorbing surfaces, resulting in reduced heat losses enabling providing still more and faster augmented net to food cooking power;
(p) enabling the cooker cavity to warm up to a temperature of convenience for the food being cooked, shielding said first and/or third window partly or wholly with said insulating slabs, whenever temperature threatens to exceed allowable temperature limits for foods, beverages and/or cooker materials;
(q) enabling supervision of cooking progress and/or performing stirring or food turning operations conveniently by lifting off momentarily said cover cavity or said insulating slab, heat continuing to be supplied to said food from below by said first heat conducting tray;
(r) enabling continued cooking and/or warm-keeping of hot foods in late solar afternoons when the sun goes down and ambient temperature drops and enabling warm-keeping of cooked foods on the eating table and/or the eating place by serving said cooked food in one or more of said first trays, kept warm by said insulation on said outer walls of said support frame of said trays and by said insulating slabs over the apertures of said trays;
(s) enabling cooking operations and/or warm-keeping of hot foods by means of a halogen light source, electricity being supplied for example from one or more of said batteries charged by said one or more PV cell modules;
(t) enabling augmented electricity generation alternating with and/or simultaneously with and/or independent of cooking operations by positioning one or more PV cell modules under and/or sideways from said bendable mirror for optimum irradiation of PV cell modules by said bendable mirror;
(u) enabling cooling of one or more of said PV cell module means by providing under said PV cell module means one or more air channel means communicating with one or more air channel means and/or chimney means incorporated in and/or on said bendable mirror means;
(v) enabling varied cooking operations, cooking foods directly on said trays, for example of the classical type, the steam-cooking type, the stir-frying type, the baking type, the grilling type;
(w) enabling water purification by heat and light by providing said first tray, optionally also said second tray, as a highly light transparent tray made of an anti-reflectivity coated low-iron glass or a polymer, such as for example polyethylene terephthalate (PET)/polybutylene terephthalate (PBT), acrylic, polycarbonate;
(x) enabling cooking of soups, heating water and/or other liquids in a cooker cavity positioned in approximately vertical position in said half-barrel shaped concave reflective cavity, parallel to said axis of rotation of said half-barrel shape, said cooker cavity having an opening in its top for receiving liquids and preferably having said spectrally selective surfaces as all of its outside surfaces, facing light, transmitted from all sides by said transparent low iron glass cavity or said transparent polymer cavity, positioned at an optimum distance around said cooker cavity;
(y) enabling purification of drinking water by heat and light by means of a light transparent glass or polymer cavity, suitable for holding water, positioned approximately vertically in said half-barrel shaped concave reflective cavity parallel to said axis of rotation of said half-barrel shape, said transparent cavity being also capable of accommodating or receiving and holding transparent glass or polymer bottles containing water;
(z) protecting PV cell modules, glazings of said windows and other cooker materials upon finalizing operations, by providing said bendable mirror with dimension at least sufficient in horizontal (off-duty) flat position to cover and protect itself and said cooker structure, said windows or trays and said PV cell modules against overheating, hail, rain, dust or sand storms, winds, debris, vandalism and the like.

2.-49. (canceled)
